(19) United States
(12) Patent Application Publication
(10) Pub. No.: US 2025/0151259 A1
(43) Pub. Date: May 8, 2025

(54) SEMICONDUCTOR DEVICE

(71) Applicant: Samsung Electronics Co., Ltd., Suwon-si (KR)

(72) Inventors: Hongjun Lee, Suwon-si (KR); Keunnam Kim, Suwon-si (KR); Kiseok Lee, Suwon-si (KR)

(21) Appl. No.: 18/657,885

(22) Filed: May 8, 2024

(30) Foreign Application Priority Data
Nov. 8, 2023 (KR) 10-2023-0153932

(51) Int. Cl. H10B 12/00; G11C 11/16; G11C 11/4091

(52) U.S. Cl. CPC H10B 12/482; G11C 11/1655; G11C 11/1657; G11C 11/4091; H10B 12/485; H10B 12/488; H10B 12/0335

(57) ABSTRACT

Provided is a semiconductor device including a first word line extending in a first direction, bit lines extending in a second direction different from the first direction in a plan view, a second word line between ones of the bit lines and extending in the second direction, and a first memory cell. The first memory cell may include a first transistor electrically connected to a first one of the bit lines and the first word line, a second transistor electrically connected to the second word line and including source/drain electrodes, and a capacitor electrically connected to the second transistor. One of the source/drain electrodes of the second transistor may be electrically connected to the first transistor.

### CROSS-REFERENCE TO RELATED APPLICATIONS

This application is based on and claims priority under 35 U.S.C. § 119 to Korean Patent Application No. 10-2023-0153932, filed on Nov. 8, 2023, in the Korean Intellectual Property Office, the disclosure of which is incorporated by reference herein in its entirety.

### BACKGROUND OF THE INVENTION

The inventive concepts relate to semiconductor devices, and more particularly, to semiconductor memory devices including capacitors.

Recently, with the rapid development of miniaturized semiconductor processing technology, the area of unit cells is decreasing as the high integration of semiconductor devices is accelerated. Therefore, the area that a capacitor may occupy within a unit cell is also decreasing. For example, as the integration of semiconductor devices such as dynamic random-access memories (DRAMs) increases, the area of a unit cell decreases, but required capacitance is maintained or increased. Therefore, there is a demand for semiconductor devices to overcome spatial limitations and design rule limitations.

### SUMMARY OF THE INVENTION

The inventive concepts provide a semiconductor device that may be manufactured through an easy method.

The inventive concepts provide a semiconductor device with improved characteristics.

In addition, the technical goals to be achieved by the inventive concepts are not limited to the technical goals mentioned above, and other technical goals will be understood by one of ordinary skill in the art from the following descriptions.

According to some aspects of the inventive concepts, there is provided a semiconductor device including a first word line extending in a first direction, bit lines extending in a second direction different from the first direction in a plan view, a second word line between ones of the bit lines and extending in the second direction, and a first memory cell, wherein the first memory cell includes a first transistor electrically connected to a first one of the bit lines and the first word line, a second transistor electrically connected to the second word line and including source/drain electrodes, and a capacitor electrically connected to the second transistor, and wherein one of the source/drain electrodes of the second transistor is electrically connected to the first transistor.

According to some aspects of the inventive concepts, there is provided a semiconductor device including a first memory cell and a second memory cell adjacent to each other, wherein each of the first memory cell and the second memory cell includes a first transistor, a second transistor, and a capacitor, a first word line electrically connected to the first transistor of each of the first memory cell and the second memory cell, a bit line electrically connected to the first transistor of each of the first memory cell and the second memory cell, and second word lines electrically connected to the second transistor of the first memory cell and the second transistor of the second memory cell, respectively.

According to some aspects of the inventive concepts, there is provided a semiconductor device including active patterns protruding from a substrate, first word line patterns between the active patterns and extending in a first direction in a plan view, a device isolation layer on the substrate and between the active patterns and the first word line patterns, bit lines on the active patterns and the first word line patterns, crossing the active patterns and the first word line patterns in the plan view, and extending in a second direction in the plan view, first contact patterns between the active patterns and the bit lines and contacting the active patterns and the bit lines, second word line patterns on the device isolation layer and between the bit lines in the plan view, second contact patterns between the bit lines and the second word line patterns and contacting the active patterns, and landing pads on the second contact patterns and electrically connected to the second contact patterns, wherein the second word line patterns extend in the second direction, and wherein the second direction is different from the first direction.

### BRIEF DESCRIPTION OF THE DRAWINGS

Embodiments of the present inventive concepts will be more clearly understood from the following detailed description taken in conjunction with the accompanying drawings, in which:

FIG. 1A is a circuit diagram of a semiconductor device according to some embodiments;

FIG. 1B is a circuit diagram of a semiconductor device according to some embodiments;

FIG. 1C is a circuit diagram of a first memory cell and a second memory cell of the semiconductor device of FIG. 1A;

FIG. 2A is a diagram illustrating currents flowing through a first memory cell and a second memory cell when a first word line is deactivated, a first sub-word line is activated, and a second sub-word line is deactivated;

FIG. 2B is a diagram illustrating currents flowing through a first memory cell and a second memory cell when the first word line is activated, the first sub-word line is activated, and the second sub-word line is deactivated;

FIG. 2C is a diagram illustrating currents flowing through a first memory cell and a second memory cell when the first word line is activated, the first sub-word line is deactivated, and the second sub-word line is deactivated;

FIG. 2D is a diagram illustrating currents flowing through a first memory cell and a second memory cell when the first word line is activated, the first sub-word line is deactivated, and the second sub-word line is activated;

FIG. 3A is a graph showing voltages applied to a bit line, a first word line, and a second word line in a first read operation on a first memory cell and a second memory cell, according to some embodiments;

FIG. 3B is a graph showing voltages applied to a bit line, a first word line, and second word lines in a first write operation on a first memory cell and a second memory cell, according to some embodiments;

FIG. 4A is a plan view for describing the layout of a semiconductor device according to some embodiments;

FIG. 4B is a cross-sectional view taken along a line A-A′ and a cross-sectional view taken along a line B-B′ of the semiconductor device of FIG. 4A;

FIG. 4C is a cross-sectional view taken along a line C-C′ and a cross-sectional view taken along a line D-D′ of the semiconductor device of FIG. 4A;

FIG. 4D is an enlarged view of a region D of FIG. 4C; and

FIGS. 5A, 5B, 6A, 6B, 7A, 7B, 8A, 8B, 9A, 9B, 10A, 10B, 11A, 11B, 12A, 12B, 13A, 13B, 14A, 14B, 15A, 15B, 16A, 16B, 17A, 17B, 18A, 18B, 19A, 19B, 20A, 20B, 21A, 21B, 22A, 22B, 23A, 23B, 24A, 24B, 25A, and 25B are diagrams for describing a method of manufacturing a semiconductor device, according to some embodiments.

### DETAILED DESCRIPTION

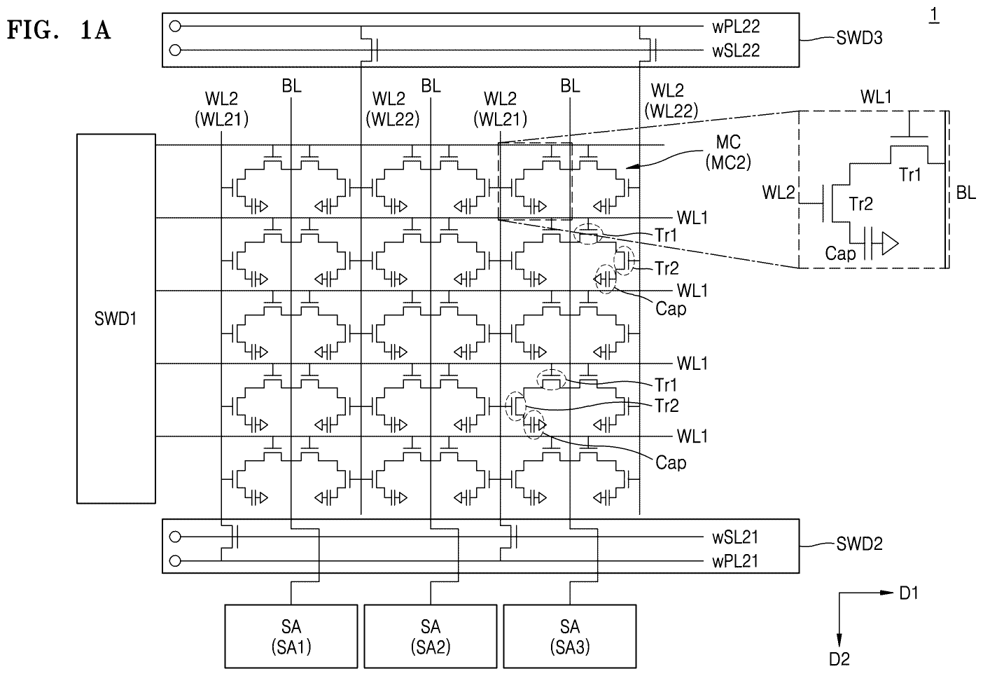

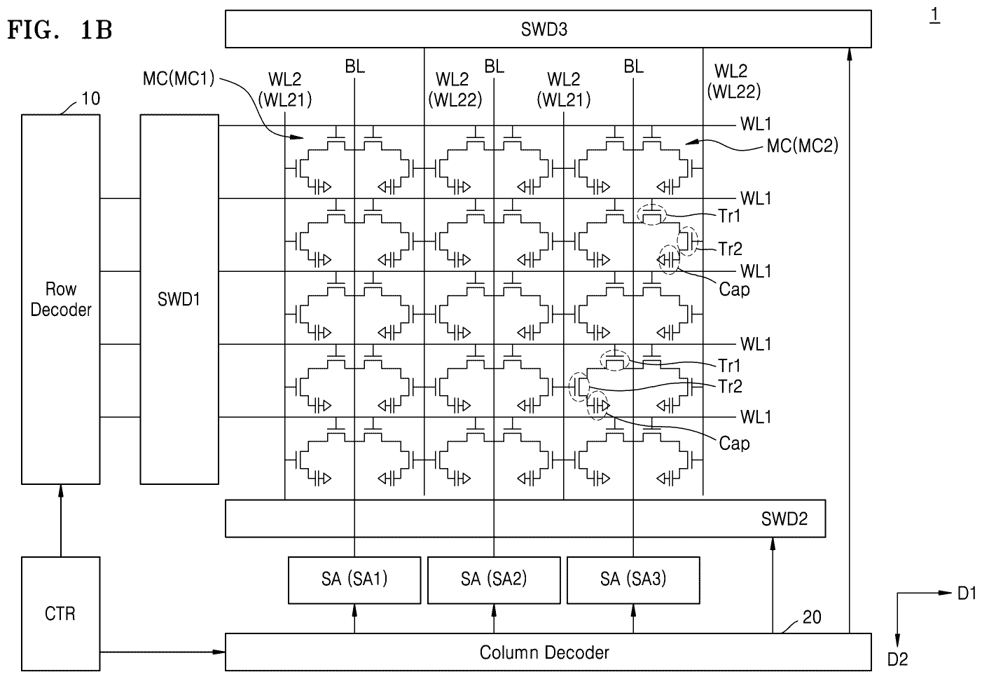

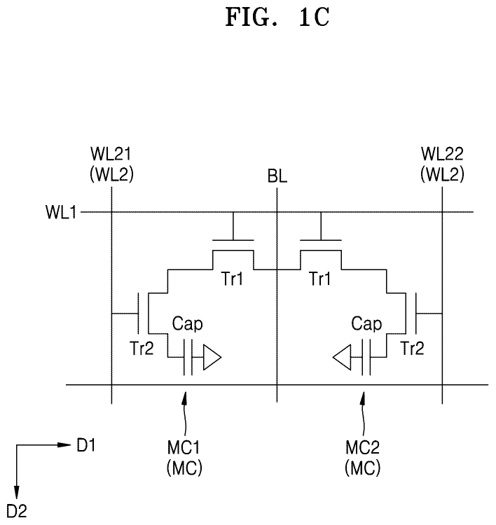

FIG. 1A is a circuit diagram of a semiconductor device according to some embodiments. FIG. 1B is a circuit diagram of a semiconductor device according to some embodiments.

Referring to FIGS. 1A and 1B, a semiconductor device 1 may be a memory device. The semiconductor device 1 may include a memory cell array, bit lines BL, first word lines WL1, and second word lines WL2. The semiconductor device 1 may further include at least one from a first word line driver SWD1, a second word line driver SWD2, a third word line driver SWD3, and sense amplifiers SA. The semiconductor device 1 may further include a control logic CTR, a row decoder 10, and a column decoder 20, as shown in FIG. 1B. The column decoder 20 may be connected to the sense amplifiers SA, the second word line driver SWD2, and the third word line driver SWD3. As used herein, “an element A connected to an element B” (or similar language) means that the element A is physically and/or electrically connected to the element B.

The memory cell array may include a plurality of memory cells MC. The memory cells MC may be arranged in a first direction D1 and a second direction D2. The memory cells MC may each be connected to a bit line BL, a first word line WL1, and a second word line WL2. For example, the memory cells MC may each be connected between the bit line BL and the first word line WL1 and between the first word line WL1 and the second word line WL2.

A plurality of first word lines WL1 may be provided. The first word lines WL1 may extend in the first direction D1. The first word lines WL1 may be spaced apart from each other (e.g., in the second direction D2). The first word lines WL1 may be connected to the first word line driver SWD1. The first word line driver SWD1 may be connected to the row decoder 10. The row decoder 10 may decode an externally input address and select at least one of the first word lines WL1. An address decoded by the row decoder 10 may be provided to the first word line driver SWD1, and, in response to control by the control logic CTR, the first word line driver SWD1 may provide a certain voltage to at least one selected first word line WL1 and unselected first word lines WL1, respectively. For example, the first word line driver SWD1 may apply a first voltage to the at least one selected first word line WL1.

A plurality of bit lines BL may be provided. The bit lines BL may each extend in the second direction D2. The second direction D2 may be a direction different from the first direction D1. For example, the second direction D2 may intersect the first direction D1. The bit lines BL may be spaced apart from each other (e.g., in the first direction D1). The bit lines BL may be connected to the sense amplifiers SA, respectively. The sense amplifiers SA may sense data stored in the memory cells MC that are electrically connected to the sense amplifiers SA through corresponding bit lines BL, respectively.

The sense amplifiers SA may include, for example, a first sense amplifier SA1, a second sense amplifier SA2, and a third sense amplifier SA3. The first sense amplifier SA1 may be connected to one of the bit lines BL, the second sense amplifier SA2 may be connected to another one of the bit lines BL, and the third sense amplifier SA3 may be connected to an additional one of the bit lines BL. The number of sense amplifiers SA may be identical to the number of bit lines BL but is not limited thereto.

As shown in FIG. 1B, the column decoder 20 may provide a data transmission path between the sense amplifiers SA and an external device (e.g., a memory controller). The column decoder 20 may be connected to the bit lines BL. The column decoder 20 may select at least one of the bit lines BL by decoding an externally input address. The sense amplifiers SA may detect, amplify, and output the voltage difference between at least one bit line BL selected according to an address decoded by the column decoder 20 and a reference bit line. Alternatively, a reference voltage or a supply voltage may be applied to at least one selected bit line BL.

The control logic CTR may control the row decoder 10, the column decoder 20, and the sense amplifiers SA. The control logic CTR may generate control signals for controlling operations of writing or reading data to or from the memory cells MC.

A plurality of second word lines WL2 may be provided. As shown in FIG. 1A, a plurality of second word lines WL2 may each be disposed between ones of the bit lines BL. The second word lines WL2 extend in the second direction D2 and may be spaced apart from each other (e.g., in the first direction D1). The second word lines WL2 may be arranged between ones of the bit lines BL and may be spaced apart from the bit lines BL (e.g., in the first direction D1). The second word lines WL2 may include first sub-word lines WL21 and second sub-word lines WL22. The second sub-word lines WL22 may be arranged between ones of the first sub-word lines WL21. The bit lines BL may each be disposed between one of the first sub-word lines WL21 and a corresponding one of the second sub-word lines WL22.

As shown in FIG. 1A, the second word line driver SWD2 may include a first word power line wPL21 and a first selection line wSL21. The first word power line wPL21 and the first selection line wSL21 may be provided adjacent to each other.

The first sub-word lines WL21 may be connected to the first word power line wPL21. The second sub-word lines WL22 may not be connected to the first word power line wPL21. For example, the second sub-word lines WL22 may be spaced apart and electrically separated from the first word power line wPL21.

The second word line driver SWD2 may be connected to the column decoder 20, as shown in FIG. 1B. The column decoder 20 may select at least one of the second word lines WL2 by decoding an externally input address. For example, the column decoder 20 may select at least one of the first sub-word lines WL21, and an address decoded by the column decoder 20 may be provided to the second word line driver SWD2. The second word line driver SWD2 may provide certain voltages to at least one selected first sub-word line WL21 and unselected first sub-word lines WL21 in response to the control of the control logic CTR. For example, the second word line driver SWD2 may apply a first power voltage to the at least one selected first sub-word line WL21. The second word line driver SWD2 may be disposed adjacent to the sense amplifiers SA.

As shown in FIG. 1A, the third word line driver SWD3 may include a second word power line wPL22 and a second selection line wSL22. The second word power line wPL22 and the second selection line wSL22 may be provided adjacent to each other. The second sub-word lines WL22 may be electrically connected to the second word power line wPL22. The first sub-word lines WL21 may not be connected to the second word power line wPL22. For example, the first sub-word lines WL21 may be spaced apart and electrically separated from the second word power line wPL22. The first word power line wPL21 may be spaced apart and electrically separated from the second word power line wPL22. The third word line driver SWD3 may be separated from the second word line driver SWD2 with the memory cell array therebetween, but the inventive concepts are not limited thereto.

The third word line driver SWD3 may be connected to the column decoder 20, as shown in FIG. 1B. The column decoder 20 may select at least one of the second sub-word lines WL22 by decoding an externally input address. An address decoded by the column decoder 20 may be provided to the third word line driver SWD3. The third word line driver SWD3 may provide certain voltages to at least one selected second sub-word line WL22 and unselected second sub-word lines WL22 in response to the control of the control logic CTR. For example, the third word line driver SWD3 may apply a second power voltage to the at least one selected second sub-word line WL22. Hereinafter, for simplicity of explanation, descriptions are given of a single first word line WL1, a single bit line BL, and a single second word line WL2.

The memory cells MC may each include a first transistor Tr1, a second transistor Tr2, and a capacitor Cap, as shown in FIG. 1A. The first word line WL1 and the bit line BL may each be electrically connected to the first transistor Tr1. For example, a gate electrode of the first transistor Tr1 may be connected to the first word line WL1, and source/drain electrodes of the first transistor Tr1 may be connected to the bit line BL and the second transistor Tr2, respectively.

The second word line WL2 may be electrically connected to the second transistor Tr2. For example, a gate electrode of the second transistor Tr2 may be electrically connected to the second word line WL2. Source/drain electrodes of the second transistor Tr2 may be connected to the first transistor Tr1 and the capacitor Cap, respectively. Therefore, the capacitor Cap may be electrically connected to the first transistor Tr1 through the second transistor Tr2.

FIG. 1C is a circuit diagram of a first memory cell and a second memory cell of the semiconductor device 1 of FIG. 1A.

Referring to FIG. 1C together with FIG. 1A, the memory cells MC may include a first memory cell MC1 and a second memory cell MC2 that are adjacent to each other. The first memory cell MC1 and the second memory cell MC2 may share one bit line BL and one first word line WL1. For example, the bit line BL and the first word line WL1 may be electrically connected to the first transistor Tr1 of the first memory cell MC1 and the first transistor Tr1 of the second memory cell MC2. In detail, the bit line BL may be connected to one of the source/drain electrodes of the first transistor Tr1 of the first memory cell MC1 and one of the source/drain electrodes of the first transistor Tr1 of the second memory cell MC2.

The first memory cell MC1 may be electrically connected to a first sub-word line WL21 and electrically separated from a second sub-word line WL22. For example, a gate electrode of the second transistor Tr2 of the first memory cell MC1 may be connected to the first sub-word line WL21.

The second memory cell MC2 may be electrically connected to the second sub-word line WL22 and electrically separated from the first sub-word line WL21. For example, a gate electrode of the second transistor Tr2 of the second memory cell MC2 may be connected to the second sub-word line WL22.

Referring back to FIG. 1A, the first sub-word line WL21 that is between bit lines BL adjacent to each other may be electrically connected to the first memory cell MC1 and the second memory cell MC2. In other words, ones of the memory cells MC between the bit lines BL adjacent to each other may share the first sub-word line WL21.

The second sub-word line WL22 that is between the bit lines BL adjacent to each other may be electrically connected to the first memory cell MC1 and the second memory cell MC2. In other words, ones of the memory cells MC between the bit lines BL adjacent to each other may share the second sub-word line WL22.

According to some embodiments, since the second word line WL2 is provided between ones of the bit lines BL adjacent to each other, the total number of bit lines BL may be reduced. For example, the number of bit lines BL for the same number of cells may be reduced by half as compared to that of the prior case. Therefore, the pitch of the bit lines BL may increase. Thus, even when the semiconductor device 1 becomes highly integrated and miniaturized, the bit lines BL may be fabricated more easily.

The bit lines BL may be connected to the sense amplifiers SA, respectively. Since the number of bit lines BL decreases, the number of sense amplifiers SA may also decrease. Therefore, limits on the planar area of the sense amplifiers SA may be reduced. The gain (e.g., source-drain gain) characteristics of the sense amplifiers SA may thus be improved.

The sense amplifiers SA may be electrically connected to pad terminals (not shown) of the semiconductor device 1 through connection wires (not shown). The pad terminals of the semiconductor device 1 may be configured to be connected to terminals of an external device, and thus the semiconductor device 1 may be electrically connected to the external device. The external device may include, for example, a semiconductor device such as a memory device or a memory controller. The memory device may include dynamic random-access memory (DRAM) but is not limited thereto. According to some embodiments, since the number of bit lines BL is reduced, the number of pad terminals may be reduced. Therefore, the arrangement of the pad terminals may be designed more freely. Furthermore, the pad terminals and connection wires may be manufactured more easily.

As used herein, the first transistor Tr1, the second transistor Tr2, and the capacitor Cap of each memory cell MC may also be referred to as a first transistor device Tr1, a second transistor device Tr2, and a capacitor device Cap, respectively.

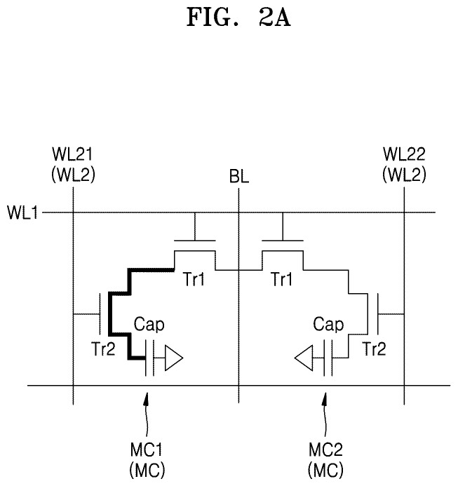

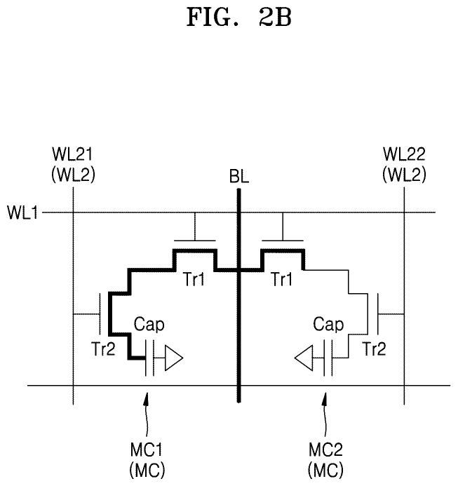

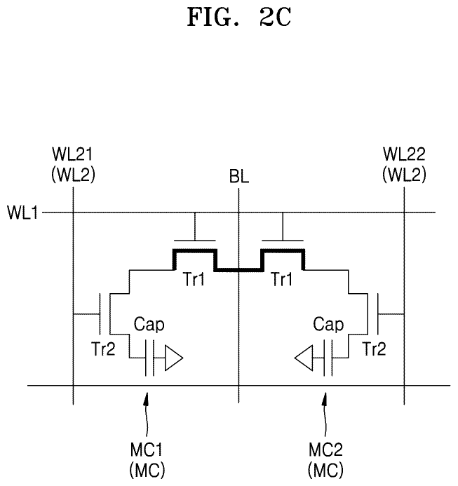

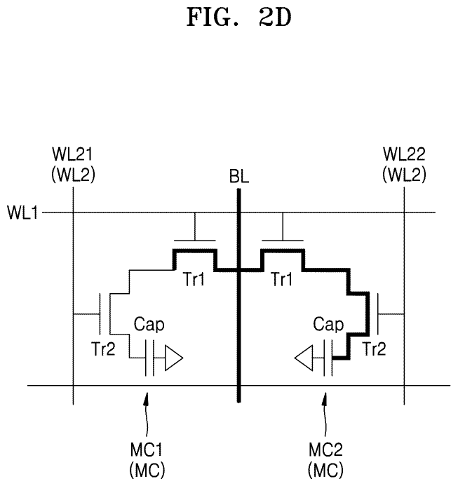

FIG. 2A is a diagram illustrating currents flowing through a first memory cell and a second memory cell when a first word line is deactivated, a first sub-word line is activated, and a second sub-word line is deactivated.

Referring to FIG. 2A, when the first word line WL1 is deactivated, the first sub-word line WL21 is activated, and the second sub-word line WL22 is deactivated, the first transistor Tr1 of the first memory cell MC1 may be in an off state, and the second transistor Tr2 of the first memory cell MC1 may be turned on. The first transistor Tr1 and the second transistor Tr2 of the second memory cell MC2 may be in an off state.

FIG. 2B is a diagram illustrating currents flowing through a first memory cell and a second memory cell when the first word line is activated, the first sub-word line is activated, and the second sub-word line is deactivated.

Referring to FIG. 2B, when the first word line WL1 is activated, the first sub-word line WL21 is activated, and the second sub-word line WL22 is deactivated, the first transistor Tr1 of the first memory cell MC1 may be turned on, and the second transistor Tr2 of the first memory cell MC1 may be turned on. Therefore, charges stored in the capacitor Cap of the first memory cell MC1 are shared with the bit line BL, and thus charge sharing may occur between the bit line BL and the first memory cell MC1. The first transistor Tr1 of the second memory cell MC2 may be turned on and the second transistor Tr2 of the second memory cell MC2 may be in an off state.

FIG. 2C is a diagram illustrating currents flowing through a first memory cell and a second memory cell when the first word line is activated, the first sub-word line is deactivated, and the second sub-word line is deactivated.

Referring to FIG. 2C, when the first word line WL1 is activated, the first sub-word line WL21 is deactivated, and the second sub-word line WL22 is deactivated, the first transistor Tr1 of the first memory cell MC1 and the first transistor Tr1 of the second memory cell MC2 may be turned on. The second transistor Tr2 of the first memory cell MC1 and the second transistor Tr2 of the second memory cell MC2 may be in an off state.

FIG. 2D is a diagram illustrating currents flowing through a first memory cell and a second memory cell when the first word line is activated, the first sub-word line is deactivated, and the second sub-word line is activated.

Referring to FIG. 2D, when the first word line WL1 is activated, the first sub-word line WL21 is deactivated, and the second sub-word line WL22 is activated, the first transistor Tr1 of the second memory cell MC2 and the second transistor Tr2 of the second memory cell MC2 may be turned on. Therefore, charges stored in the capacitor Cap of the second memory cell MC2 are shared with the bit line BL, and thus charge sharing may occur between the bit line BL and the second memory cell MC2. The first transistor Tr1 of the first memory cell MC1 may be turned on and the second transistor Tr2 of the first memory cell MC1 may be in an off state.

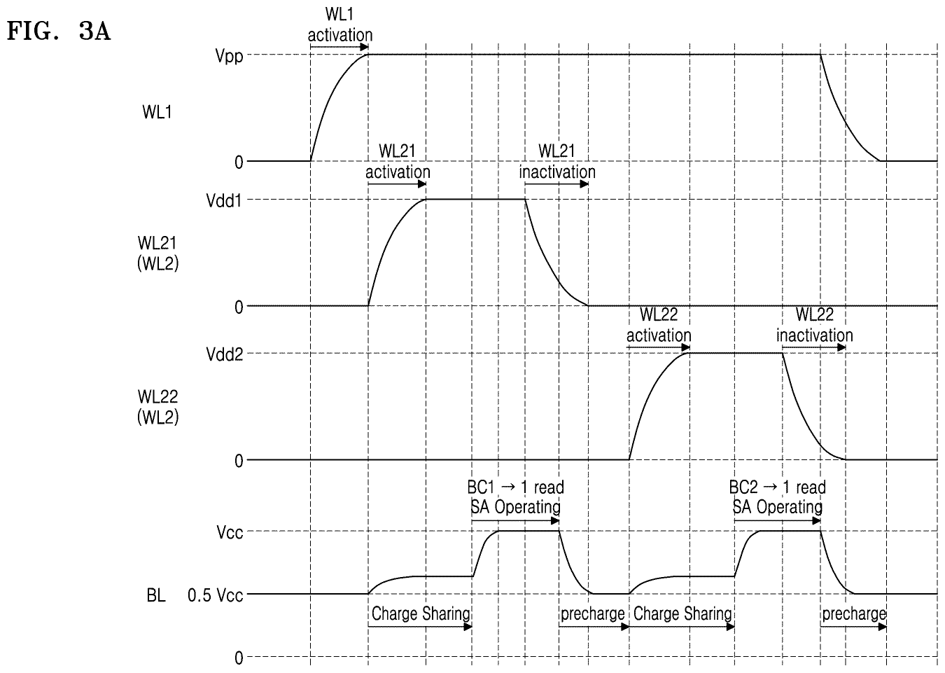

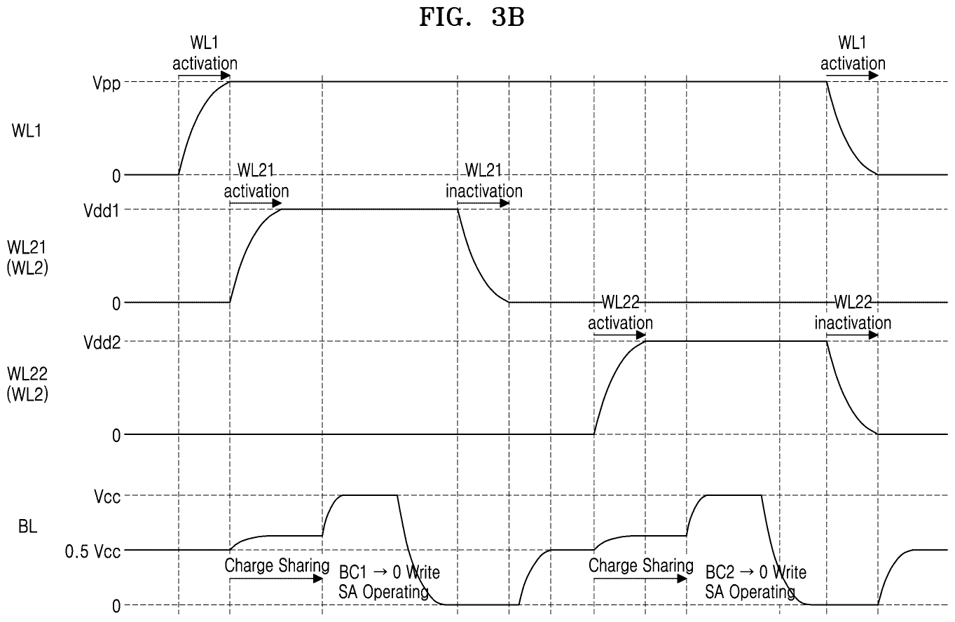

FIG. 3A is a graph showing voltages applied to a bit line, a first word line, and a second word line in a first read operation on a first memory cell and a second memory cell, according to some embodiments. Hereinafter, a first read operation according to some embodiments is described. For simplicity, descriptions are given with respect to a single sense amplifier.

Referring to FIG. 3A together with FIGS. 1A to 1C, the bit line BL may be charged with a reference voltage 0.5 Vcc. Afterwards, a first voltage Vpp may be applied to the first word line WL1. Therefore, as described above with reference to FIG. 2C, the first word line WL1 may be activated and the first transistor Tr1 of the first memory cell MC1 may be turned on. The first voltage Vpp may be a high voltage or a pumping voltage. The first voltage Vpp may be greater than the reference voltage 0.5 Vcc. At this time, a first power voltage Vdd1 is not applied to the first sub-word line WL21, and thus the first sub-word line WL21 may be in a deactivated state. Since a second power voltage Vdd2 is not applied to the second sub-word line WL22, the second sub-word line WL22 may be in a deactivated state. Therefore, the second transistor Tr2 of the first memory cell MC1 and the second transistor Tr2 of the second memory cell MC2 may be in an off state.

By decoding an externally input address, the first sub-word line WL21 may be selected. A decoded address is transmitted to the second word line driver (SWD2 of FIG. 1A), and the second word line driver SWD2 may apply the first power voltage Vdd1 to the selected first sub-word line WL21. The first sub-word line WL21 may be activated, and the second transistor Tr2 of the first memory cell MC1 may be turned on, as described above with reference to FIG. 2B. Charges stored in the capacitor Cap of the first memory cell MC1 are shared with the bit line BL, and thus charge sharing may occur between the bit line BL and the first memory cell MC1. Charges stored in the capacitor Cap of the first memory cell MC1 may move to the bit line BL, and thus a supply voltage Vcc may be applied to the bit line BL. A sense amplifier (SA of FIG. 1A) connected to the bit line BL may operate and detect the supply voltage Vcc through a first buried contact BC1 and the bit line BL. The first buried contact BC1 may refer to a portion of the first memory cell MC1 that is electrically connected to a drain electrode of the second transistor Tr2 and an electrode of the capacitor Cap. The sense amplifier SA may sense data stored in the capacitor Cap of the first memory cell MC1 through the bit line BL. Data stored in the capacitor Cap of the first memory cell MC1 may be “1” but is not limited thereto.

Application of the first power voltage Vdd1 may be stopped, and thus the first sub-word line WL21 may be deactivated. The second transistor Tr2 of the first memory cell MC1 may be turned off. The bit line BL may be pre-charged.

The second power voltage Vdd2 may be applied to the second sub-word line WL22, and thus the second sub-word line WL22 may be activated. Therefore, as described with reference to FIG. 2D, the second transistor Tr2 of the second memory cell MC2 may be turned on. Charges stored in the capacitor Cap of the second memory cell MC2 are shared with the bit line BL, and thus charge sharing may occur between the bit line BL and the second memory cell MC2. Charges stored in the capacitor Cap of the second memory cell MC2 may move to the bit line BL, and thus a supply voltage Vcc may be applied to the bit line BL. The sense amplifier (SA of FIG. 1A) may operate and sense the supply voltage Vcc through a second buried contact BC2 and the bit line BL. The second buried contact BC2 may refer to a portion of the second memory cell MC2 that is electrically connected to the drain electrode of the second transistor Tr2 and an electrode of the capacitor Cap. The sense amplifier SA may sense data stored in the capacitor Cap of the second memory cell MC2 through the bit line BL. Data stored in the capacitor Cap of the second memory cell MC2 may be “1” but is not limited thereto.

Application of the second power voltage Vdd2 may be stopped, and thus the second sub-word line WL22 may be deactivated. Therefore, the second transistor Tr2 of the second memory cell MC2 may be turned off. The bit line BL may be pre-charged.

Unlike the descriptions given above, a second read operation may be performed on the semiconductor device 1. In the second read operation, data stored in the first memory cell MC1 or data stored in the second memory cell MC2 may be “0”.

FIG. 3B is a graph showing voltages applied to a bit line, a first word line, and second word lines in a first write operation on a first memory cell and a second memory cell, according to some embodiments. Hereinafter, a first write operation according to some embodiments is described.

Referring to FIG. 3B, as the first voltage Vpp is applied to the first word line WL1, the first word line WL1 may be activated, and the first transistor Tr1 of the first memory cell MC1 may be turned on, as described above with reference to FIG. 2C. Before application of the first voltage Vpp, the bit line BL may be pre-charged with a reference voltage. At this time, the first power voltage Vdd1 is not applied to the first sub-word line WL21, and thus the first sub-word line WL21 may be in a deactivated state. Since the second power voltage Vdd2 is not applied to the second sub-word line WL22, the second sub-word line WL22 may be in a deactivated state. Therefore, the second transistor Tr2 of the first memory cell MC1 and the second transistor Tr2 of the second memory cell MC2 may be in an off state.

The first power voltage Vdd1 may be applied to the first sub-word line WL21. The first sub-word line WL21 may be activated, and the second transistor Tr2 of the first memory cell MC1 may be turned on, as described above with reference to FIG. 2B. Charges stored in the capacitor Cap of the first memory cell MC1 are shared with the bit line BL, and thus charge sharing may occur between the bit line BL and the first memory cell MC1. Charges stored in the capacitor Cap of the first memory cell MC1 may move to the bit line BL, and thus a supply voltage Vcc may be applied to the bit line BL. A sense amplifier (SA of FIG. 1A) connected to the bit line BL may operate. A low voltage may be applied to the bit line BL, and thus charges of the capacitor Cap in the first memory cell MC1 may move to the bit line BL through the first transistor Tr1 and the second transistor Tr2. Therefore, the capacitor Cap of the first memory cell MC1 is discharged, and data may be written to the first memory cell MC1. The low voltage may be 0 V but is not limited thereto. Data written to the first memory cell MC1 may be “0”, and the first write operation may be an operation of writing “0”. However, the inventive concepts are not limited thereto.

Application of the first power voltage Vdd1 may be stopped, and thus the first sub-word line WL21 may be deactivated. The second transistor Tr2 of the first memory cell MC1 may be turned off.

The second power voltage Vdd2 may be applied to the second sub-word line WL22, and thus the second sub-word line WL22 may be activated. Therefore, as described with reference to FIG. 2D, the second transistor Tr2 of the second memory cell MC2 may be turned on. Charges stored in the capacitor Cap of the second memory cell MC2 are shared with the bit line BL, and thus charge sharing may occur between the bit line BL and the second memory cell MC2. Charges stored in the capacitor Cap of the second memory cell MC2 may move to the bit line BL, and thus a supply voltage Vcc may be applied to the bit line BL. A sense amplifier (SA of FIG. 1A) connected to the bit line BL may operate. A low voltage such as 0 V may be applied to the bit line BL, and thus charges may move from the capacitor Cap in the second memory cell MC2 to the bit line BL through the first transistor Tr1 and the second transistor Tr2. Therefore, the capacitor Cap of the second memory cell MC2 is discharged and data may be written to the second memory cell MC2. Data written to the second memory cell MC2 may be “0” but is not limited thereto.

Application of the second power voltage Vdd2 may be stopped, and thus the second sub-word line WL22 may be deactivated. Therefore, the second transistor Tr2 of the second memory cell MC2 may be turned off.

Unlike the descriptions given above, a second write operation may be performed on the semiconductor device 1. In the second write operation, data “1” may be written to at least one of the first memory cell MC1 or the second memory cell MC2.

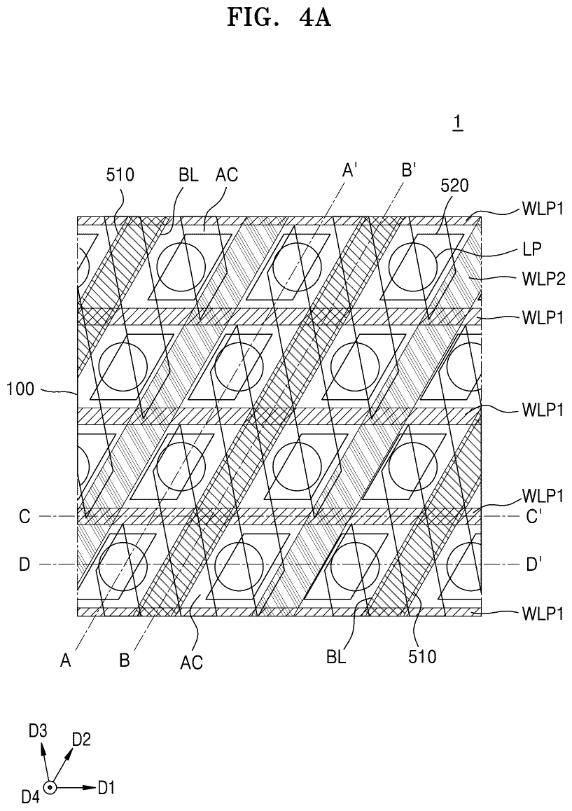

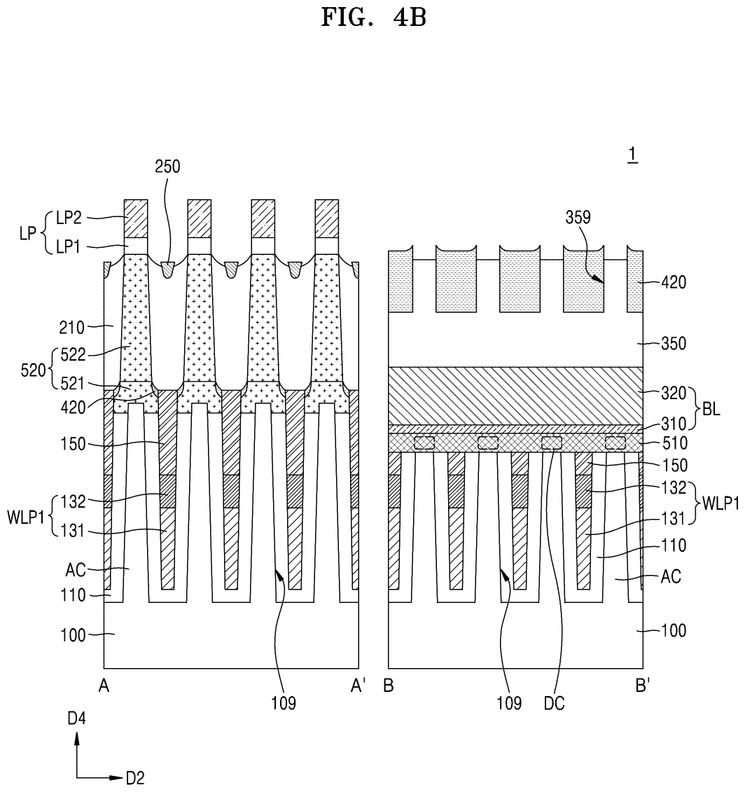

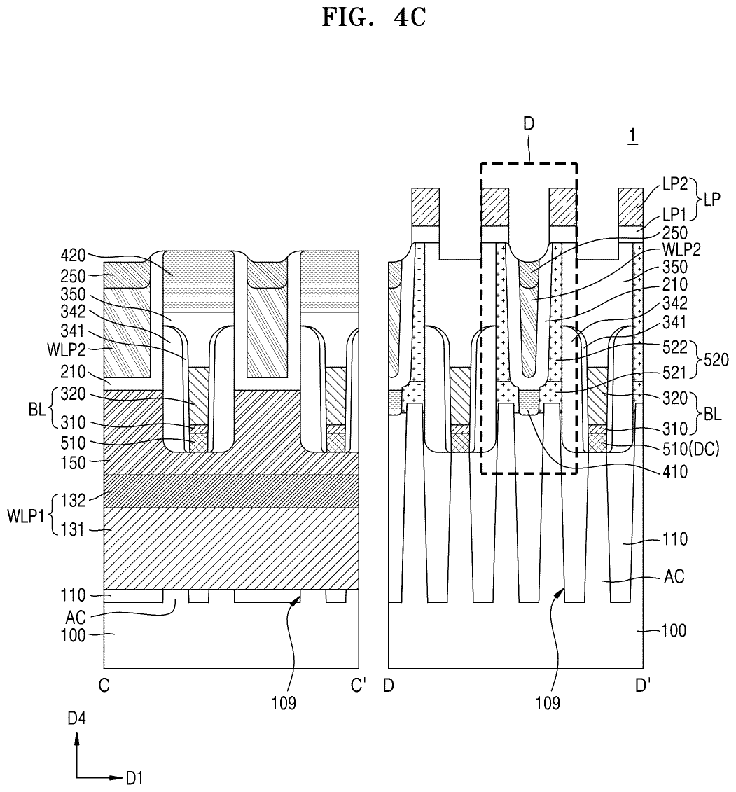

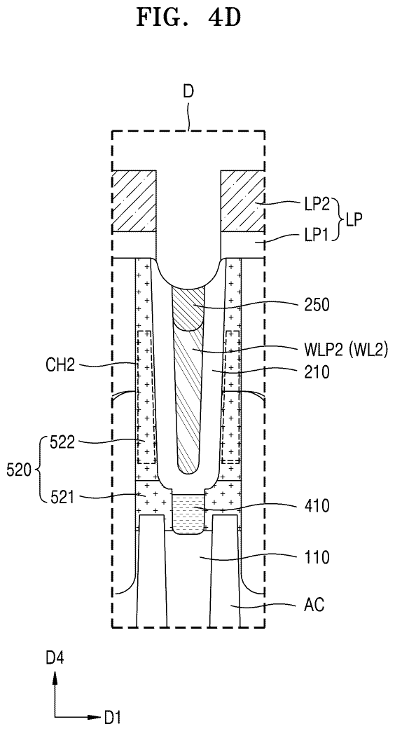

FIG. 4A is a plan view illustrating the layout of a semiconductor device according to some embodiments. FIG. 4B is a cross-sectional view taken along a line A-A′ and a cross-sectional view taken along a line B-B′ of the semiconductor device of FIG. 4A. FIG. 4C is a cross-sectional view taken along a line C-C′ and a cross-sectional view taken along a line D-D′ of the semiconductor device of FIG. 4A. FIG. 4D is an enlarged view of a region D of FIG. 4C. FIGS. 4A, 4B, 4C, and 4D are described below with reference to FIGS. 1A to 1C.

Referring to FIGS. 4A, 4B, 4C, and 4D, the semiconductor device 1 may include a substrate 100, active patterns AC, a device isolation layer 110, first word line patterns WLP1, first bit lines BL, second word line patterns WLP2, gate insulation patterns 210, first contact patterns 510, second contact patterns 520, and landing pads LP.

The substrate 100 may be a semiconductor substrate. The substrate 100 may include, for example, a semiconductor material such as silicon or germanium. In another example, the substrate 100 may include a compound semiconductor such as silicon carbide (SiC) and/or gallium arsenide (GaAs). In another example, the substrate 100 may be a silicon-on-insulator (SOI) substrate. The substrate 100 may include a conductive region, e.g., a well doped with an impurity or a region doped with an impurity.

The first direction D1 may be parallel to the bottom surface of the substrate 100. The second direction D2 may be parallel to the bottom surface of the substrate 100 and may intersect the first direction D1. The angle between the first direction D1 and the second direction D2 may be in a range from 1 degree to 179 degrees. For example, the angle between the first direction D1 and the second direction D2 may be in a range from 1 degree to 90 degrees but is not limited thereto. A third direction D3 may be parallel to the bottom surface of the substrate 100 and may intersect the first direction D1 and the second direction D2. A fourth direction D4 may be substantially perpendicular to the bottom surface of the substrate 100. The fourth direction D4 may be a vertical direction.

The active patterns AC may be provided on the substrate 100. The active patterns AC may protrude from the top surface of the substrate 100. The active patterns AC may be integrated with the substrate 100. The device isolation layer 110 may be disposed in device isolation trenches 109. The device isolation layer 110 may include silicon oxide, silicon nitride, or a combination thereof. The active patterns AC may be defined by the device isolation layer 110. For example, the device isolation layer 110 may be on the substrate 100 between the active patterns AC and the first word line patterns WLP1.

The active patterns AC may each have longitudinal axes extending in the third direction D3 in a plan view, as shown in FIG. 4A. The active patterns AC may be arranged in the first direction D1 and the second direction D2. The active patterns AC may be spaced apart from one another in the first direction D1, the second direction D2, and the third direction D3.

The first word line patterns WLP1 may cross the active patterns AC in a plan view and extend in the first direction D1. The first word line patterns WLP1 may be spaced apart from each other in the second direction D2. The bit lines BL may extend in the second direction D2 on the first word line patterns WLP1 and across the first word line patterns WLP1. The first contact patterns 510 may cross the active patterns AC and extend in the second direction D2. The first contact patterns 510 may overlap the bit lines BL in a plan view. For example, the first contact patterns 510 may overlap the bit lines BL in the fourth direction D4. As used herein, “an element A overlaps an element B in a direction X” (or similar language) means that there is at least one straight line that extends in the direction X and intersects both the elements A and B. The bit lines BL may be connected to the active patterns AC through the first contact patterns 510. The second word line patterns WLP2 may cross the active patterns AC in a plan view and extend in the second direction D2. The second word line patterns WLP2 may be disposed between the bit lines BL in a plan view and may be spaced apart from the bit lines BL. The second word line patterns WLP2 may cross the first word line patterns WLP1 on the first word line patterns WLP1. The landing pads LP may be arranged on the second contact patterns 520 and may overlap the active patterns AC in a plan view. For example, the landing pads LP may overlap the active patterns AC in the fourth direction D4. The landing pads LP may be electrically connected to the active patterns AC through the second contact patterns 520. More detailed descriptions of the bit lines BL, second word line patterns WLP2, first contact patterns 510, second contact patterns 520, and landing pads LP are given below.

The first word line patterns WLP1 may be in (e.g., may be buried in) the device isolation layer 110, as shown in FIG. 4B. For example, sidewalls and bottom surfaces of the first word line patterns WLP1 may be surrounded by the device isolation layer 110. It will be understood that “an element A surrounds an element B” (or similar language) as used herein means that the element A is at least partially around the element B but does not necessarily mean that the element A completely encloses the element B. For example, the first word line patterns WLP1 may be between the active patterns AC.

The first word line patterns WLP1 may each include any one of the first word lines WL1 of FIGS. 1A to 1C and gate electrodes of a plurality of first transistors Tr1. Here, the gate electrodes of the plurality of first transistors Tr1 may be connected to any one of the first word lines WL1. For example, one of the first word lines WL1 of FIGS. 1A to 1C may be formed integrally with the gate electrodes of the first transistors Tr1 connected thereto. Therefore, a first portion of each of the first word line patterns WLP1 may function as the first word line WL1 of FIGS. 1A to 1C, and second portions of the first word line patterns WLP1 may respectively function as the gate electrodes of the first transistors Tr1 of FIGS. 1A to 1C.

The first transistors Tr1 may be buried channel transistors. The active patterns AC and the substrate 100 may have first channel regions. The first channel regions may be provided on the sidewalls and the bottom surfaces of the first word line patterns WLP1. The first channel regions may function as channels of the first transistors Tr1. Therefore, the first transistors Tr1 may each have a buried channel structure, and thus the channel lengths of the first transistors Tr1 may be increased. The device isolation layer 110 may have gate insulation regions. The gate insulation regions may function as gate insulation layers of the first transistors Tr1. The gate insulation regions may be provided between the first word line patterns WLP1 and the active patterns AC and between the first word line patterns WLP1 and the substrate 100.

The first word line patterns WLP1 may each include a first conductive pattern 131 and a second conductive pattern 132. The first conductive pattern 131 may be connected to the active patterns AC, as shown in FIG. 4C. The first conductive pattern 131 may include a metal material such as tungsten, tantalum, copper, and/or aluminum.

The second conductive pattern 132 is disposed on the first conductive pattern 131 and may be on (e.g., may cover) the top surface of the first conductive pattern 131. The second conductive pattern 132 may function as a work function adjusting layer. For example, the second conductive pattern 132 may prevent the generation of a leakage current of the first transistors (Tr1 of FIGS. 1A to 1C). The second conductive pattern 132 may include a material different from that of the first conductive pattern 131. The second conductive pattern 132 may include doped polysilicon. For example, the second conductive pattern 132 may include polysilicon, and the polysilicon may be doped with a Group III element or a Group V element. For example, the polysilicon may contain impurities such as phosphorus (P), arsenic (As), bismuth (Bi), and/or antimony (Sb) at a relatively high concentration.

The semiconductor device 1 may further include first capping patterns 150. The first capping patterns 150 may be arranged on the first word line patterns WLP1 and may be on (e.g., may cover) the top surfaces of the first word line patterns WLP1. The top surface of each of the first word line patterns WLP1 may correspond to the top surface of a corresponding second conductive pattern 132. The first capping patterns 150 may include a silicon-containing nitride. The silicon-containing nitride may include, for example, silicon nitride, silicon carbonitride, and/or silicon oxynitride. The top surfaces of the first capping patterns 150 may be arranged at a higher level than the top surfaces of the active patterns AC in the fourth direction D4. As used herein, the term “level” refers to a height in the fourth direction D4 with the bottom surface of the substrate 100 providing a base reference plane. That is, a level may be taken in the fourth direction D4 relative to the bottom surface of the substrate 100.

The bit lines BL may be arranged on (e.g., over) the first capping patterns 150, the device isolation layer 110, and the active patterns AC. The bottom surfaces of the bit lines BL may be arranged at a higher level than the top surfaces of the first word line patterns WLP1 in the fourth direction D4. The bit lines BL may be vertically spaced apart and electrically insulated from the first word line patterns WLP1 by the first capping patterns 150. For example, the bit lines BL may be on the active patterns AC and the first word line patterns WLP1 and may cross the active patterns AC and the first word line patterns WLP1 in a plan view.

The first contact patterns 510 may be provided between the active patterns AC and the bit lines BL and may contact the top surfaces of the active patterns AC and the bottom surfaces of the bit lines BL. The first contact patterns 510 may include direct contacts DC, respectively. The direct contacts DC may be provided between the bit lines BL and the active patterns AC. The bit lines BL may be electrically connected to the active patterns AC through the direct contacts DC. The direct contacts DC may each be provided between one bit line BL and one source/drain electrode from among source/drain electrodes of the first transistor Tr1 in FIG. 1A. The source/drain electrodes of the first transistor Tr1 may include first source/drain regions. Some of the first source/drain regions may be provided in the active patterns AC and contact the direct contacts DC. The first contact patterns 510 may be further provided between the device isolation layer 110 and the bit lines BL and between the first capping patterns 150 and the bit lines BL. For example, the first contact patterns 510 may extend between the first word line patterns WLP1 and the bit lines BL and between the device isolation layer 110 and the bit lines BL. The first contact patterns 510 may extend in the second direction D2 in a plan view and may be spaced apart from each other. The first contact patterns 510 may include doped polysilicon.

The bit lines BL may each include a lower conductive pattern 310 and an upper conductive pattern 320. The lower conductive pattern 310 may be disposed between a corresponding first contact pattern 510 and the upper conductive pattern 320. The bottom surface of each of the bit lines BL may correspond to the bottom surface of a corresponding lower conductive pattern 310 but is not limited thereto. The lower conductive pattern 310 may include a material different from that of the upper conductive pattern 320. The lower conductive pattern 310 may include, for example, titanium nitride (TiN), titanium silicon nitride (TiSiN), tungsten silicide, or a combination thereof. The lower conductive pattern 310 may function as a work function adjusting layer. The lower conductive pattern 310 may prevent the generation of a leakage current of the first transistors (Tr1 of FIGS. 1A to 1C). The upper conductive pattern 320 may be disposed on the lower conductive pattern 310. The upper conductive pattern 320 may include, for example, tungsten. The lower conductive pattern 310 and the upper conductive pattern 320 may each extend in the second direction D2. The top surface of a bit line BL may be the top surface of the upper conductive pattern 320.

The semiconductor device 1 may further include first spacers 341 and second spacers 342. The first spacers 341 may be provided on the sidewalls of the bit lines BL and may cover the sidewalls of the bit lines BL. The first spacers 341 may further be on (e.g., may cover) the sidewalls of the first contact patterns 510. The first spacers 341 may include an insulation material. For example, the first spacers 341 may include silicon nitride, but the inventive concepts are not limited thereto.

The second spacers 342 may be provided on the sidewalls of the first spacers 341. The second spacers 342 may be arranged between the sidewalls of the bit lines BL and the second word line patterns WLP2, between the sidewalls of the bit lines BL and the active patterns AC, and between the sidewalls of the bit lines BL and the first capping patterns 150. The first spacers 341 may be arranged between the bit lines BL and the second spacers 342. The second spacers 342 may include a silicon-based insulation material and may include a material different from that of the first spacers 341. For example, the second spacers 342 may include silicon oxide, but the inventive concepts are not limited thereto. The first spacers 341 and the second spacers 342 may extend in the second direction D2 in a plan view.

The semiconductor device 1 may further include insulation capping patterns 350. The insulation capping patterns 350 may be provided on the bit lines BL and may be on (e.g., may cover) the top surfaces of the bit lines BL. The insulation capping patterns 350 extend in the second direction D2 and may be spaced apart from each other in the first direction D1. The insulation capping patterns 350 may further extend onto the top surfaces of the first spacers 341 and the second spacers 342. The insulation capping patterns 350 may have upper trenches 359, respectively. The upper trenches 359 may extend (e.g., may penetrate) through the top surfaces of the insulation capping patterns 350. The bottom surfaces of the upper trenches 359 may be provided in the insulation capping patterns 350. The insulation capping patterns 350 may include, for example, silicon nitride.

The semiconductor device 1 may further include first insulation patterns 410 and second insulation patterns 420. The first insulation patterns 410 may be provided between the device isolation layer 110 and the gate insulation patterns 210, as shown in FIG. 4D. The first insulation patterns 410 may include, for example, silicon oxide, silicon nitride, or a combination thereof. The second insulation patterns 420 may be provided in the upper trenches 359, as shown in FIG. 4B. The second insulation patterns 420 may include, for example, silicon oxide, silicon nitride, or a combination thereof.

The second contact patterns 520 are respectively arranged on the top surfaces of the active patterns AC and may be connected to the active patterns AC. For example, the second contact patterns 520 may contact the active patterns AC. For example, the second contact patterns 520 may be between the bit lines BL and the second word line patterns WLP2. The second contact patterns 520 may be spaced apart from each other. The second contact patterns 520 may each include a lower contact pattern 521 and an upper contact pattern 522. The lower contact pattern 521 is provided on the top surface of a corresponding active pattern AC from among the active patterns AC and may further extend onto the top surface of the device isolation layer 110. For example, the lower contact pattern 521 may contact at least one of the active patterns AC. A plurality of lower contact patterns 521 may be provided, and the first capping patterns 150 may be arranged between the plurality of lower contact patterns 521. The second insulation patterns 420 may be further arranged between the lower contact patterns 521 and the first capping patterns 150. The plurality of lower contact patterns 521 may be spaced apart from each other in the second direction D2 by the first capping patterns 150 and the second insulation patterns 420. Therefore, the lower contact patterns 521 may be electrically separated from each other. The lower contact patterns 521 may include doped polysilicon. Hereinafter, descriptions are given with respect to a single lower contact pattern 521.

The upper contact pattern 522 may be provided on the lower contact pattern 521. The upper contact pattern 522 may be a contact pillar. For example, the height of the upper contact pattern 522 may be greater than the height of the lower contact pattern 521 in the fourth direction D4. As used herein, “the height of a component” (or similar language) may correspond to the distance between the bottom surface and the top surface of the component. For example, the “height of a component” (or similar language) may refer to a thickness of the component in the fourth direction D4. The upper contact pattern 522 may include doped polysilicon. However, the impurity concentration of the upper contact pattern 522 may be different from that of the lower contact pattern 521. For example, the impurity concentration of the lower contact pattern 521 may be greater than that of the upper contact pattern 522.

The second word line patterns WLP2 may be arranged on the device isolation layer 110. The second word line patterns WLP2 may be arranged between the bit lines BL in a plan view. The second word line patterns WLP2 may be arranged between the sidewalls of the first capping patterns 150 and between the sidewalls of the second contact patterns 520. The second word line patterns WLP2 may be spaced apart from the bit lines BL by the second contact patterns 520, the first spacers 341, and the second spacers 342. The second word line patterns WLP2 may be electrically separated from the bit lines BL by the first spacers 341 and the second spacers 342. The bottom surfaces of the second word line patterns WLP2 may be provided at a higher level than the bottom surfaces of the bit lines BL in the fourth direction D4. The second word line pattern WLP2 may include titanium nitride, tungsten, tungsten nitride, titanium silicon nitride (TiSiN), tungsten silicide, and/or combinations thereof.

The bottom surfaces of the second contact patterns 520 may be provided at a lower level than the bottom surfaces of the second word line patterns WLP2 in the fourth direction D4. The top surfaces of the second contact patterns 520 may be provided at a higher level than the top surfaces of the second word line patterns WLP2 in the fourth direction D4.

The second word line patterns WLP2 may each include any one of the second word lines WL2 of FIGS. 1A to 1C and gate electrodes of a plurality of second transistors Tr2. Here, the gate electrodes of the plurality of second transistors Tr2 may be connected to any one of the second word lines WL2. For example, one of the second word lines WL2 in FIGS. 1A to 1C may be formed integrally with the gate electrodes of the second transistors Tr2 connected thereto. Therefore, a first portion of each of the second word line patterns WLP2 may function as the second word line WL2 of FIGS. 1A to 1C, and second portions of the second word line patterns WLP2 may respectively function as the gate electrodes of the second transistors Tr2 of FIGS. 1A to 1C. Hereinafter, descriptions are given with respect to a single second transistor Tr2.

The second transistor Tr2 may be a vertical channel transistor (VCT). A VCT may have a channel length extending in a vertical direction (e.g., the fourth direction D4). As shown in FIG. 4D, the second contact patterns 520 may each have second source/drain regions (not shown) and a second channel region CH2. The second channel region CH2 is a channel of the second transistor Tr2, and source/drain electrodes of the second transistor Tr2 may include second source/drain regions. The second source/drain regions may be spaced apart from each other in the fourth direction D4. For example, one of the second source/drain regions may be provided in the lower contact pattern 521. Another one of the second source/drain regions may be provided above the upper contact pattern 522 and may be connected to a corresponding landing pad LP.

The second channel region CH2 may be provided between the second source/drain regions. The second channel region CH2 may be horizontally spaced apart from the second word line patterns WLP2 with the gate insulation patterns 210 therebetween. The term “horizontal” may mean a direction parallel to the bottom surface of the substrate 100. For example, the gate insulation patterns 210 may be provided between the sidewalls of the second word line patterns WLP2 and the sidewalls of the second contact patterns 520. As described above, when any one of the second word lines (WL2 of FIGS. 1A, 1B, 1C, 2B, and 2D) is activated and the second transistor (Tr2 of FIGS. 1A, 1B, 1C, 2B, and 2D) is turned on, a current may flow between the second source/drain regions along the second channel region CH2. The second contact patterns 520 may include buried contacts, respectively. The buried contacts may be electrically connected to the drain electrode of the second transistor Tr2 and an electrode of the capacitor Cap, as shown in FIGS. 1A to 1C. The buried contacts may include the first buried contact BC1 and the second buried contact BC2 of FIGS. 2A and 2B (see also FIGS. 3A and 3B).

As described above, the first channel regions of the first transistors Tr1 of FIGS. 1A to 1C may be provided in the active patterns AC and the substrate 100. The active patterns AC may further include first source/drain regions. The first source/drain regions may include first source regions and first drain regions. The first channel regions may be provided between the first source regions and the first drain regions. For example, the first source regions may be provided in the active patterns AC between the first channel regions and the first contact pattern 510. The first source regions may be connected to the direct contacts DC. The first drain regions are provided in the active patterns AC and may be electrically connected to the second contact patterns 520. For example, the first drain regions may each contact a corresponding lower contact pattern 521. When the first transistors Tr1 are turned on, currents may flow through the first channel regions between the direct contacts DC and the second contact patterns 520, due to the first transistors Tr1. For convenience of explanation, it has been described above that the first source regions are connected to the first contact patterns 510 and the first drain regions are connected to the second contact patterns 520, but the inventive concepts are not limited thereto. According to the operation of the semiconductor device 1, in some embodiments, the first drain regions may be connected to the first contact patterns 510 and the first source regions may be connected to the second contact patterns 520.

The semiconductor device 1 may further include second capping patterns 250. The second capping patterns 250 may be arranged on the second word line patterns WLP2 and may be on (e.g., may cover) the top surfaces of the second word line patterns WLP2. The second capping patterns 250 may extend in the second direction D2 in a plan view. The second capping patterns 250 may include a silicon-containing nitride.

The gate insulation patterns 210 may be provided on the sidewalls and the bottom surfaces of the second word line patterns WLP2 and may cover the sidewalls and the bottom surfaces of the second word line patterns WLP2. The gate insulation patterns 210 may be arranged between the second word line patterns WLP2 and the second contact patterns 520. The gate insulation patterns 210 may further extend between the second word line patterns WLP2 and the first capping patterns 150, between the second word line patterns WLP2 and the insulation capping patterns 350, between the second word line patterns WLP2 and the first insulation patterns 410, and between the second capping patterns 250 and the second insulation patterns 420. The top surfaces of the gate insulation patterns 210 may be provided at the same level as or a level lower than that of the top surfaces of the second insulation patterns 420 in the fourth direction D4. The gate insulation patterns 210 may include a high-k material or a silicon-based insulation material. The high-k material may have a higher dielectric constant than silicon oxide. For example, the high-k material may include aluminum oxide, hafnium oxide, zirconium oxide, and/or combinations thereof. The silicon-based insulation material may include, for example, silicon oxide, silicon nitride, or a combination thereof.

The landing pads LP may be arranged on the second contact patterns 520. For example, the landing pads LP may be connected to the second contact patterns 520. The landing pads LP may be spaced apart from each other. The landing pads LP may further extend onto the top surfaces of the insulation capping patterns 350 and the top surfaces of the gate insulation patterns 210. The landing pads LP may be electrically connected to the active patterns AC through the second contact patterns 520. The landing pads LP may overlap the active patterns AC in the fourth direction D4.

The landing pads LP may each include a first landing pad LP1 and a second landing pad LP2. The first landing pad LP1 may be a barrier layer. For example, the first landing pad LP1 may prevent a metal in the second landing pad LP2 from spreading. The first landing pad LP1 may include, but is not limited to, a conductive metal nitride such as titanium nitride (TiN), tantalum nitride (TaN), and/or tungsten nitride (WN). The second landing pad LP2 may include a metal material different from that of the first landing pad LP1. The second landing pad LP2 may include, for example, tungsten.

Although not shown, the semiconductor device 1 may further include a capacitor (Cap of FIGS. 1A to 1C). The capacitor may include a lower electrode, an upper electrode, and a dielectric layer. The dielectric layer may be disposed between the lower electrode and the upper electrode. The landing pads LP may be electrically connected to the lower electrode of the capacitor. Therefore, the lower electrode of the capacitor may be electrically connected to the active patterns AC through the landing pads LP and the second contact patterns 520.

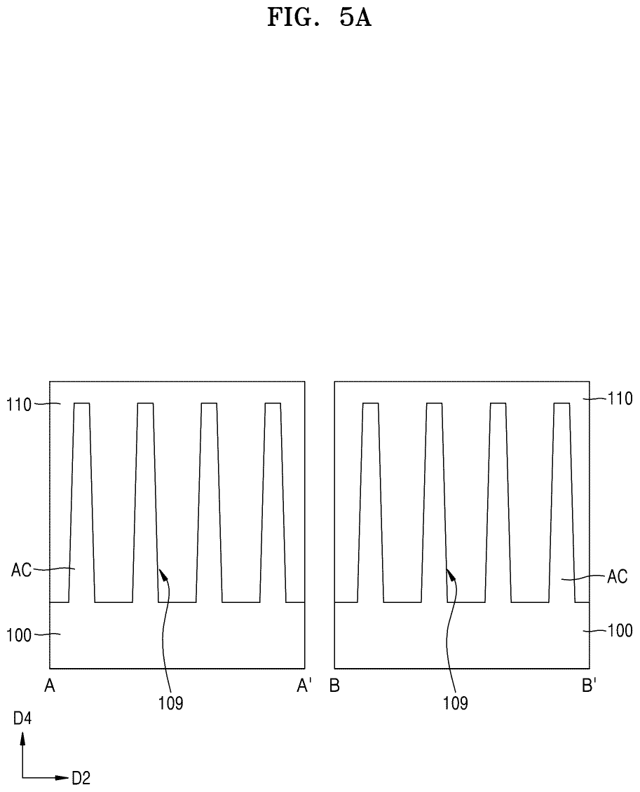

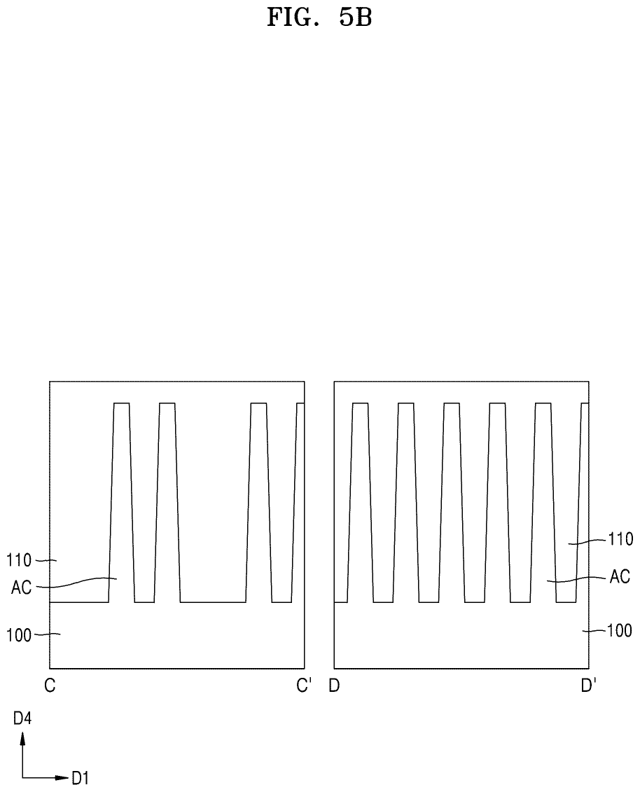

FIGS. 5A to 25B are diagrams illustrating a method of manufacturing a semiconductor device, according to some embodiments. In particular, FIGS. 5A, 6A, 7A, 8A, 9A, 10A, 11A, 12A, 13A, 14A, 15A, 16A, 17A, 18A, 19A, 20A, 21A, 22A, 23A, 24A, and 25A are diagrams corresponding to a cross-section of the semiconductor device 1 of FIG. 4A taken along a line A-A′ and a cross-section of the semiconductor device 1 of FIG. 4A taken along a line B-B′. FIGS. 5B, 6B, 7B, 8B, 9B, 10B, 11B, 12B, 13B, 14B, 15B, 16B, 17B, 18B, 19B, 20B, 21B, 22B, 23B, 24B, and 25B are diagrams corresponding to a cross-section of the semiconductor device 1 of FIG. 4A taken along a line C-C′ and a cross-section of the semiconductor device 1 of FIG. 4A taken along a line D-D′. Hereinafter, FIGS. 5A to 25B will be described with reference to FIG. 4A.

Referring to FIGS. 5A and 5B, the substrate 100 may be prepared. A first mask pattern (not shown) may be formed on the substrate 100. The first mask pattern may include a material that has an etch selectivity with respect to the substrate 100. The first mask pattern may include, for example, silicon oxide, but is not limited thereto. An etching process using the first mask pattern may be performed to form the device isolation trenches 109 in the substrate 100. The active patterns AC may be formed between the device isolation trenches 109. The active patterns AC may protrude from the top surface of the substrate 100. The active patterns AC may be doped regions of the substrate 100. Afterwards, the first mask pattern may be removed.

The device isolation trenches 109 may be filled with an insulation material, and thus the device isolation layer 110 may be formed. The device isolation layer 110 may be on (e.g., may cover) the top surfaces and the sidewalls of the active patterns AC and the bottom surfaces of the device isolation trenches 109.

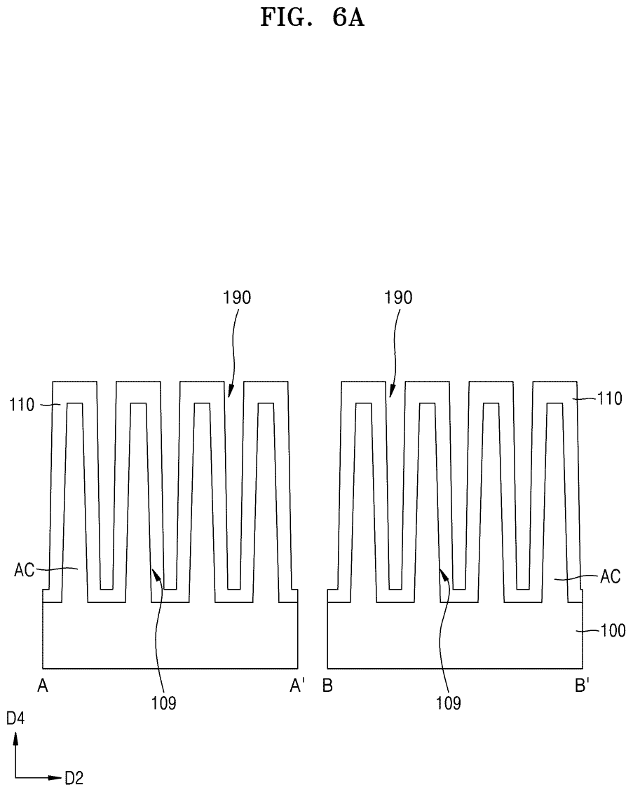

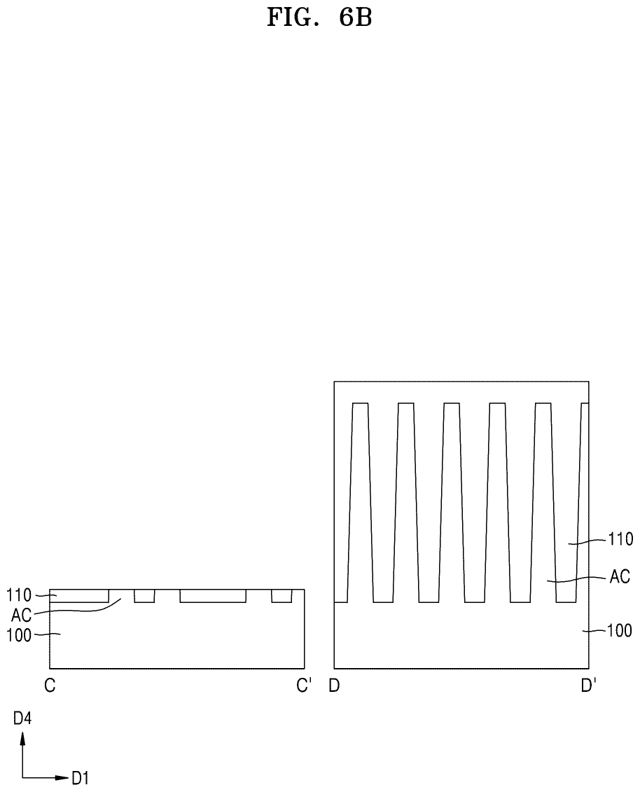

Referring to FIGS. 6A and 6B, first word line trenches 190 may be formed in the first direction D1. Formation of the first word line trenches 190 may include performing an etching process using a second mask pattern on the device isolation layer 110. A portion of the device isolation layer 110 may be removed through the etching process, and thus the first word line trenches 190 may be formed in the device isolation layer 110. The first word line trenches 190 may expose the device isolation layer 110. The first word line trenches 190 may further expose the active patterns AC. The exposed active patterns AC may be recessed through the etching process.

The first word line trenches 190 may be spaced apart from each other. The second mask pattern may be removed through a stripping process. Afterwards, an ashing process may be further performed to remove etching residues.

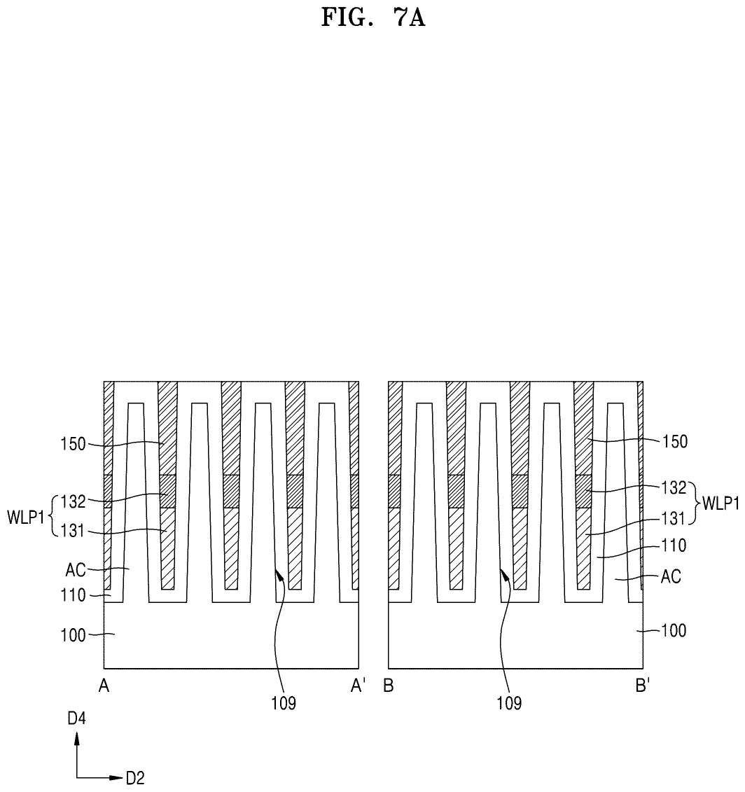

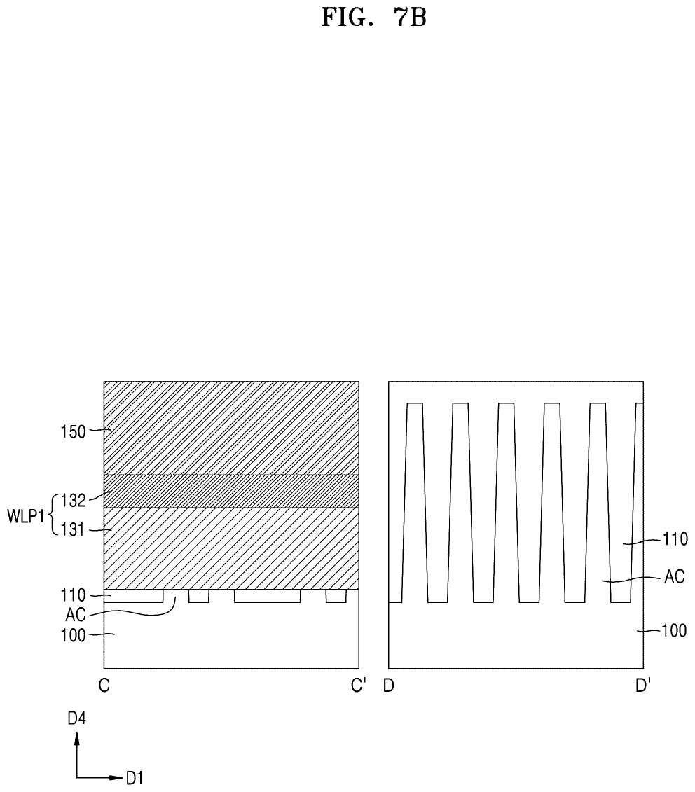

Referring to FIGS. 7A and 7B, the first word line patterns WLP1 and the first capping patterns 150 may be formed in the first word line trenches 190. The first word line patterns WLP1 may extend in the first direction D1 and may be spaced apart from each other in the second direction D2, in a plan view. The first word line patterns WLP1 may each include the first conductive pattern 131 and the second conductive pattern 132.

The first capping patterns 150 may be formed in the first word line trenches 190 and on the first word line patterns WLP1. The first capping patterns 150 may extend in the first direction D1 and may be spaced apart from each other in the second direction D2, in a plan view.

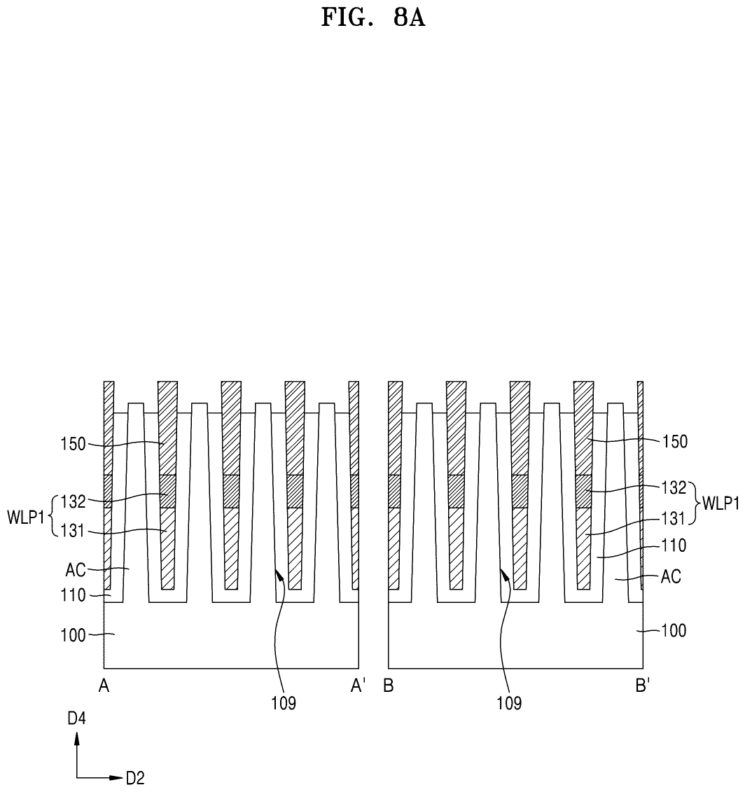

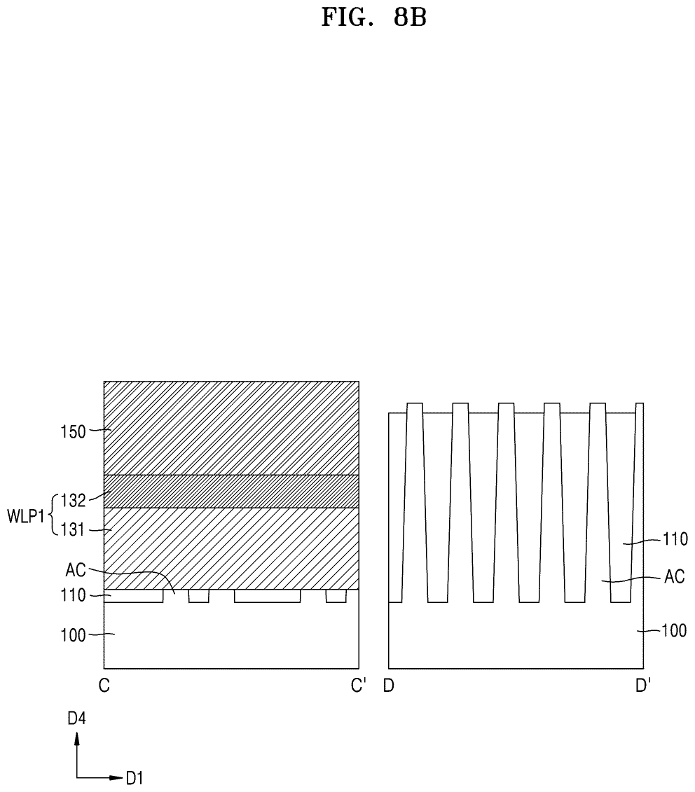

Referring to FIGS. 8A and 8B, the upper portion of the device isolation layer 110 may be removed, and thus upper portions of the first capping patterns 150 and upper portions of the active patterns AC may be exposed. The upper portion of the device isolation layer 110 may be removed through, for example, an etching process such as a wet etching process. After the etching process, for example, the top surface of the device isolation layer 110 may be provided at a lower level than the top surfaces of the first capping patterns 150 and the top surfaces of the active patterns AC in the fourth direction D4.

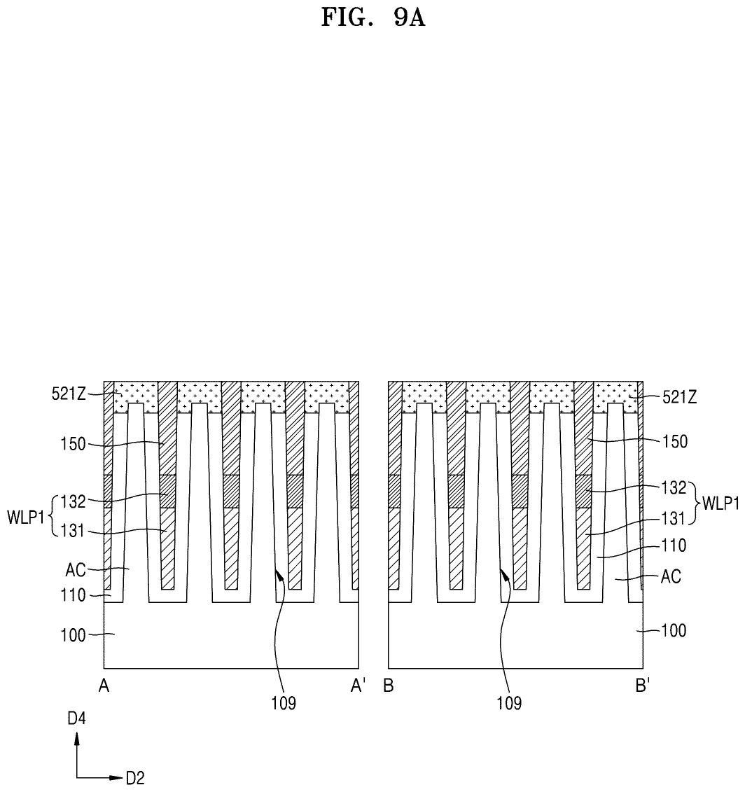

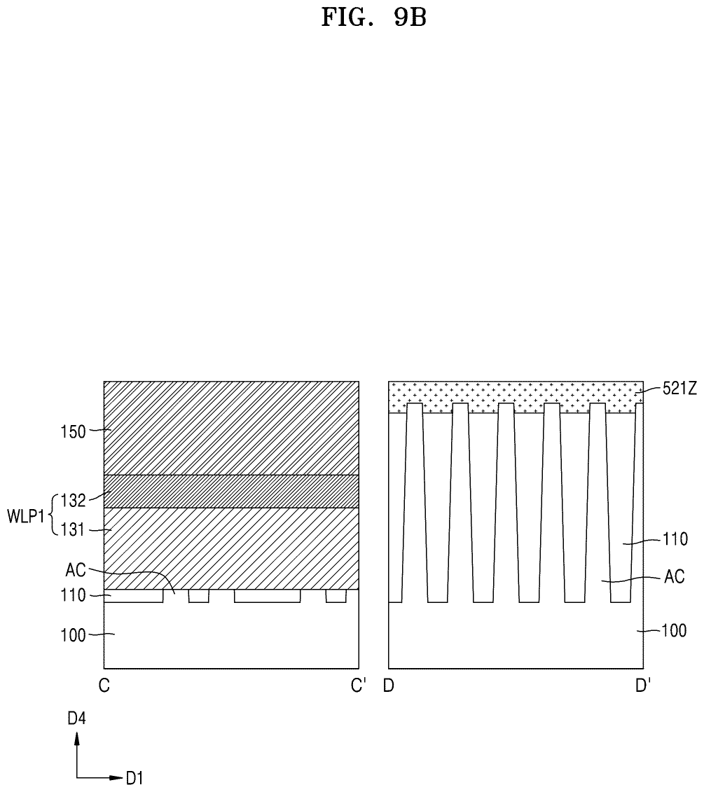

Referring to FIGS. 9A and 9B, a lower contact layer 521Z may be formed on the top surface of the device isolation layer 110 and may be on (e.g., may cover) the sidewalls of upper portions of the first capping patterns 150 and upper portions of the exposed active patterns AC.

According to some embodiments, the lower contact layer 521Z may be first formed on the top surface of the device isolation layer 110 and may be on (e.g., may cover) the top surfaces of the first capping patterns 150 and the top surfaces of the active patterns AC. A planarization process may be further performed on the lower contact layer 521Z. The planarization process may be performed through a chemical mechanical polishing (CMP) process. After the planarization process, the upper portion of the lower contact layer 521Z may be further removed to expose the top surfaces of the first capping patterns 150. For example, the upper portion of the lower contact layer 521Z may be removed through an etchback process. After the etchback process, the top surface of the lower contact layer 521Z may be provided at the same level as or a level lower than the top surfaces of the first capping patterns 150 in the fourth direction D4. For convenience, the top surface of the lower contact layer 521Z is shown to be disposed at the same level as the top surfaces of the first capping patterns 150, but the inventive concepts are not limited thereto. The lower contact layer 521Z may include, for example, polysilicon. The polysilicon may be doped with a Group III element or a Group V element.

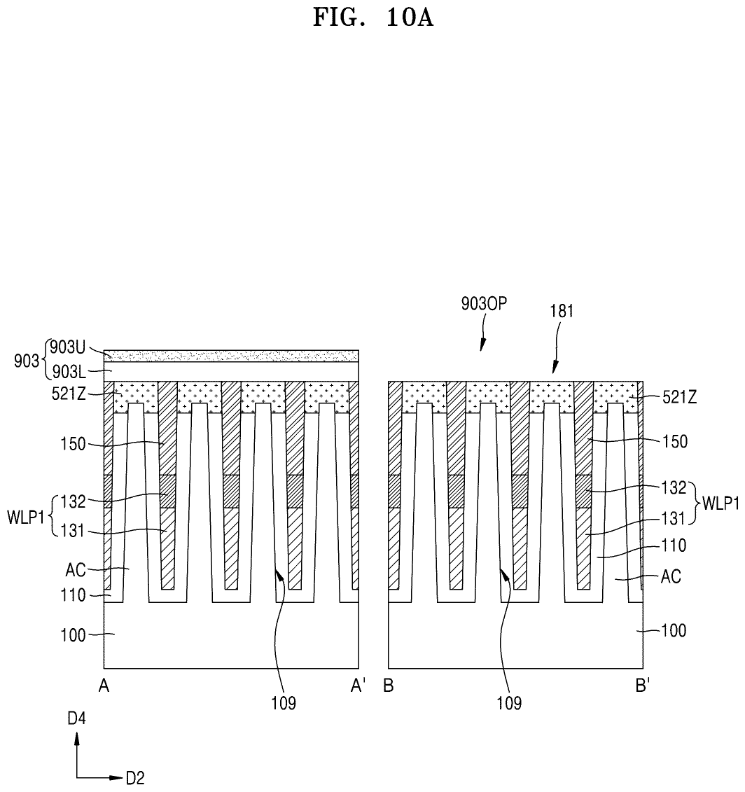

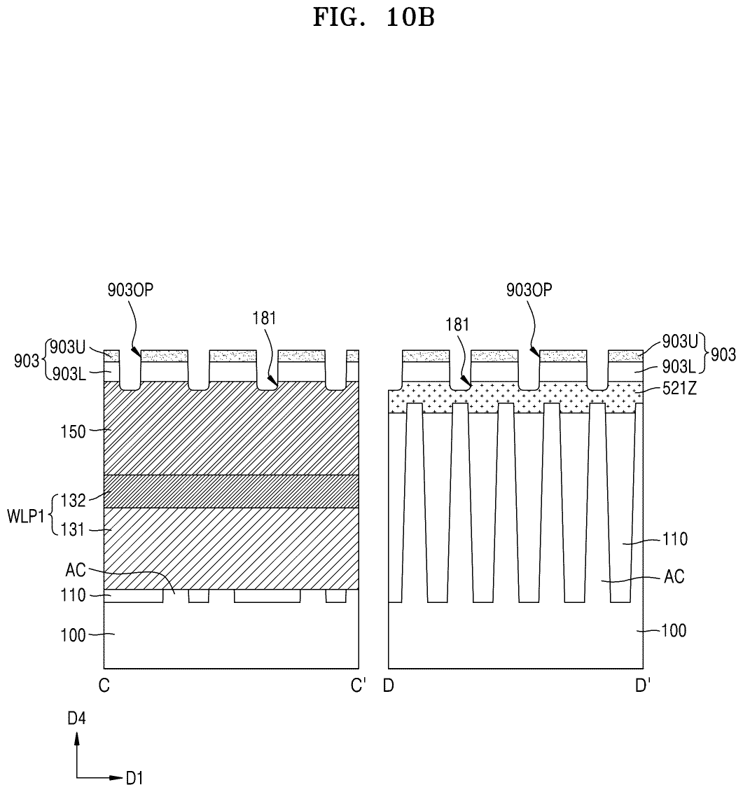

Referring to FIGS. 10A and 10B, a third mask pattern 903 may be formed on the lower contact layer 521Z and the first capping patterns 150, thereby on (e.g., covering) the top surface of the lower contact layer 521Z and the top surfaces of the first capping patterns 150. The third mask pattern 903 may include a third lower mask pattern 903L and a third upper mask pattern 903U. The third lower mask pattern 903L may include, for example, a silicon-containing insulation film such as silicon oxide or tetraethyl orthosilicate (TEOS). The third upper mask pattern 903U may be provided on the third lower mask pattern 903L. For example, the third upper mask pattern 903U may include, but is not limited to, an amorphous carbonization film. The third upper mask pattern 903U may have mask openings 903OP. The mask openings 903OP may extend in the first direction D1 in a plan view. The mask openings 903OP may expose the third lower mask pattern 903L.

An etching process using the third upper mask pattern 903U as an etch mask may be performed to form isolation trenches 181 in the third lower mask pattern 903L, the first capping patterns 150, and the lower contact layer 521Z. In the etching process, portions of the third lower mask pattern 903L exposed by the mask openings 903OP may be etched. Also, portions of the first capping patterns 150 and portions of the lower contact layer 521Z may be etched together with the portions of the third lower mask pattern 903L. The isolation trenches 181 may extend (e.g., penetrate) through the third lower mask pattern 903L and may be formed in upper portions of the first capping patterns 150 and an upper portion of the lower contact layer 521Z. The bottom surfaces of the isolation trenches 181 may be provided in the first capping patterns 150 and the lower contact layer 521Z. The isolation trenches 181 may be connected to the mask openings 903OP. The isolation trenches 181 may extend in the second direction D2 in a plan view.

Thereafter, the third upper mask pattern 903U may be removed to expose the third lower mask pattern 903L.

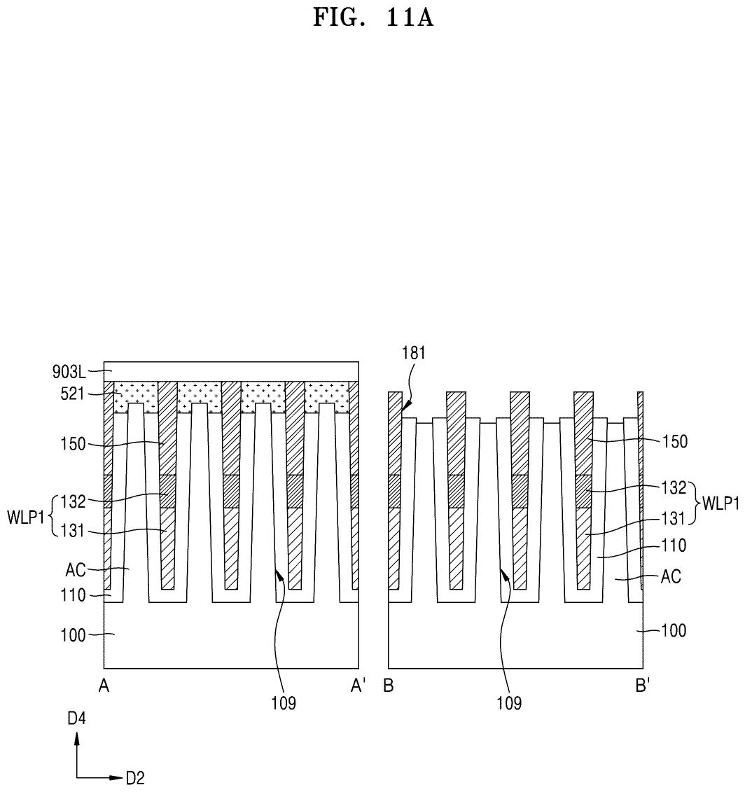

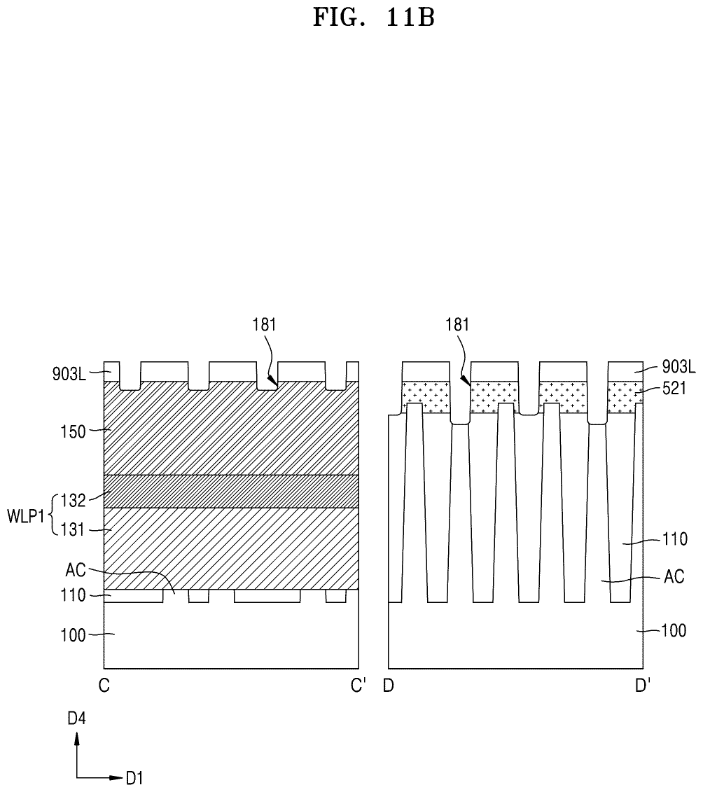

Referring to FIGS. 11A and 11B, an etching process using the third lower mask pattern 903L as an etch mask may be performed on the lower contact layer 521Z to form the plurality of lower contact patterns 521. For example, portions of the lower contact layer 521Z exposed by the isolation trenches 181 may be removed through the etching process. The lower contact patterns 521 may be spaced apart from each other in the first direction D1 and the second direction D2. The lower contact patterns 521 may expose the first capping patterns 150, the active patterns AC, and the device isolation layer 110. The top surfaces of exposed portions of the first capping patterns 150 may be further recessed through the etching process, and thus the first capping patterns 150 may have recessed top surfaces. The top surfaces of exposed portions of the active patterns AC may be further recessed through the etching process. The top surfaces of exposed portions of the device isolation layer 110 may be further recessed through the etching process. Therefore, the isolation trenches 181 may extend further downward. Hereinafter, unless otherwise specified, the top surfaces of the first capping patterns 150 may refer to surfaces provided at a higher level than the recessed top surfaces of the first capping patterns 150 in the fourth direction D4.

The third lower mask pattern 903L may be removed to expose the top surfaces of the first capping patterns 150 and the top surfaces of the lower contact patterns 521. The mask pattern may be removed through a stripping process. An ashing process may be further performed on the first capping patterns 150, lower contact patterns 521, and active patterns AC to remove etching residues.

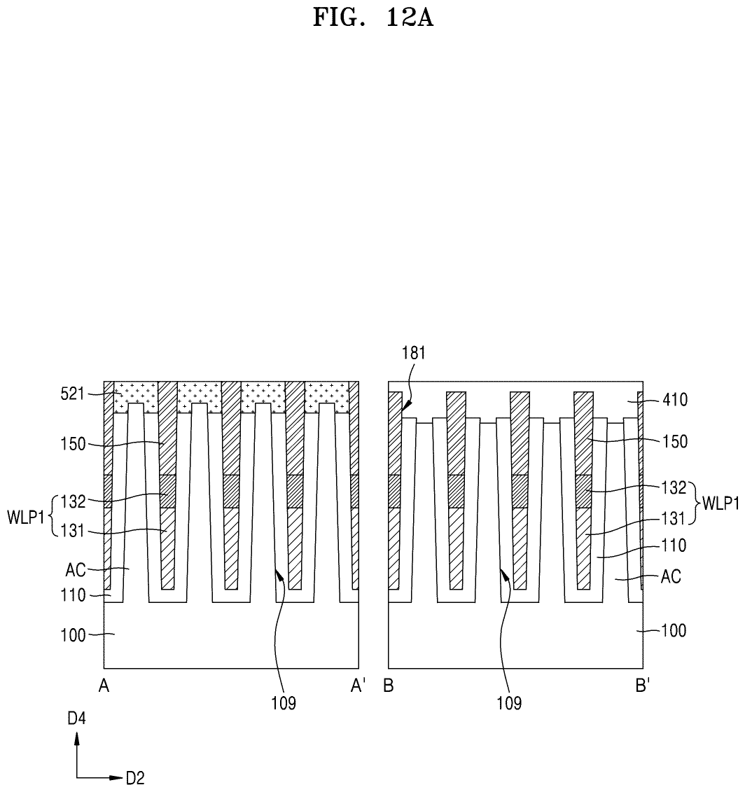

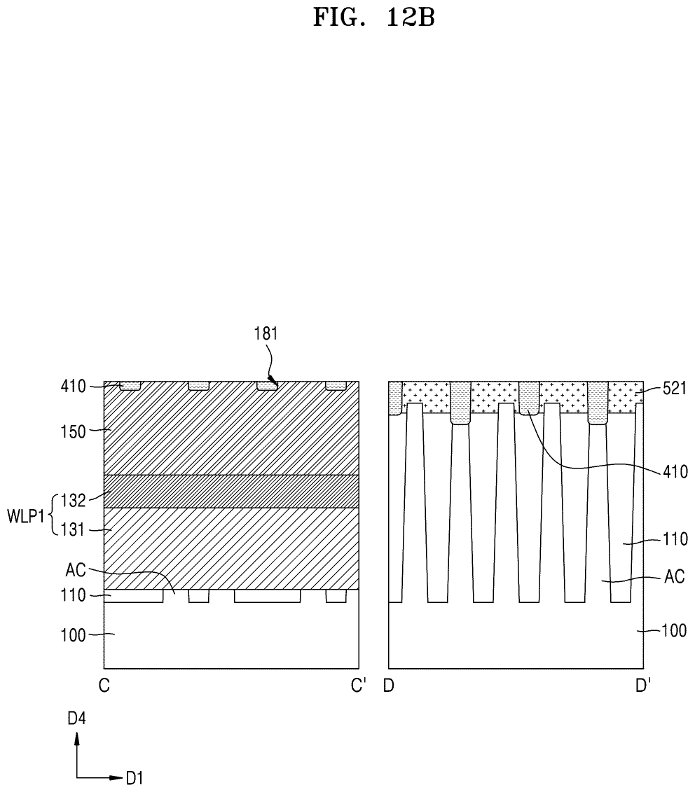

Referring to FIGS. 12A and 12B, the first insulation patterns 410 may be formed in the isolation trenches 181 and may be on (e.g., may cover) the device isolation layer 110, the active patterns AC, and the first capping patterns 150. For example, the first insulation patterns 410 may be on (e.g., may cover) the recessed top surfaces of the device isolation layer 110 and the recessed top surfaces of the active patterns AC.

Formation of the first insulation patterns 410 may include forming a first insulation layer on the lower contact patterns 521 and in the isolation trenches 181 and performing an etchback process on the first insulation layer. The first insulation layer may be formed through a deposition process. Through the etchback process, the top surfaces of the first insulation patterns 410 may be provided at the same level as or a level lower than the top surfaces of the lower contact patterns 521 in the fourth direction D4. The top surfaces of the first insulation patterns 410 may be provided at the same level as or a level lower than the top surfaces of the first capping patterns 150 in the fourth direction D4. The first insulation patterns 410 may include, for example, a silicon-containing insulation film such as silicon oxide or tetraethyl orthosilicate (TEOS). The lower contact patterns 521 may be laterally spaced apart from each other and may be electrically separated from each other by the first insulation patterns 410. Any two components that are laterally spaced apart from each other may mean that the two components are spaced from each other horizontally. As described above, the term “horizontal” may mean a direction parallel to the bottom surface of the substrate 100.

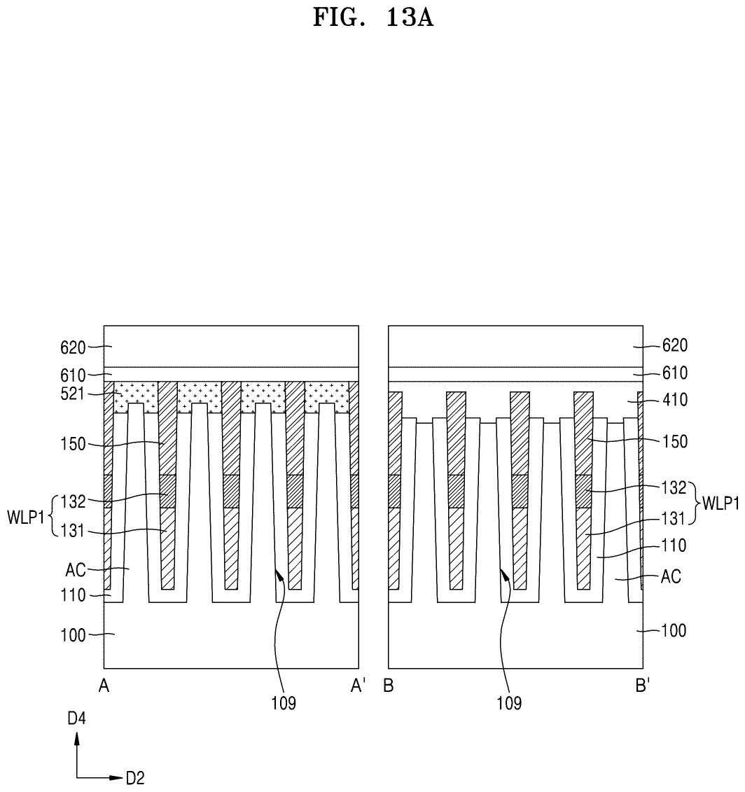

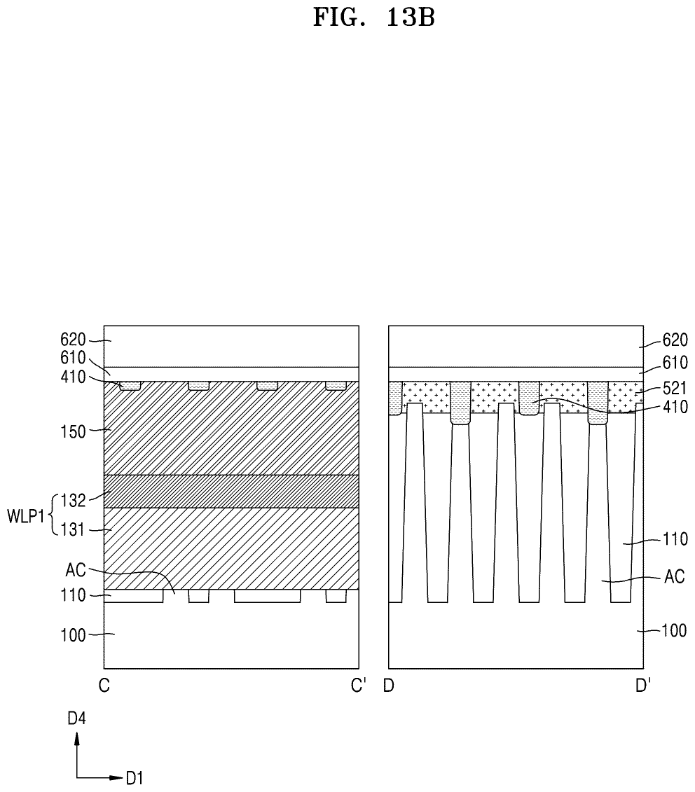

Referring to FIGS. 13A and 13B, a lower insulation layer 610 may be formed on the lower contact patterns 521, the first insulation patterns 410, and the first capping patterns 150 and may be on (e.g., may cover) the top surfaces of the lower contact patterns 521, the top surfaces of the first insulation patterns 410, and the top surfaces of the first capping patterns 150. The lower insulation layer 610 may be formed through a deposition process. The lower insulation layer 610 may include silicon nitride, silicon carbonitride, and/or silicon oxynitride. The lower insulation layer 610 may function as a buffer layer.

An upper insulation layer 620 may be formed on the top surface of the lower insulation layer 610 and may cover the lower insulation layer 610. The upper insulation layer 620 may be formed through a deposition process. The upper insulation layer 620 may include a material different from that of the lower insulation layer 610. The upper insulation layer 620 may include a silicon-containing insulation layer such as silicon oxide or tetraethyl orthosilicate (TEOS).

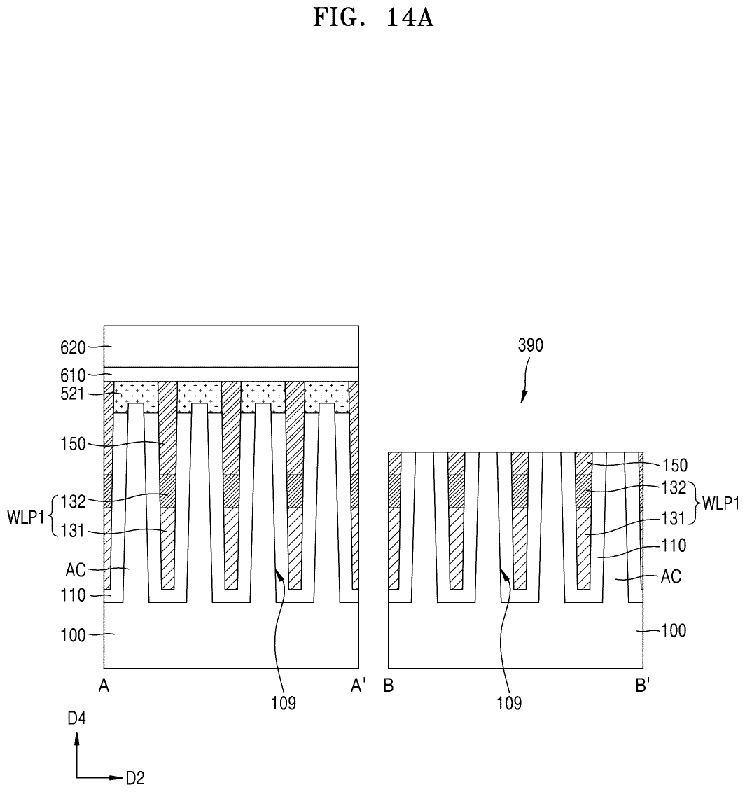

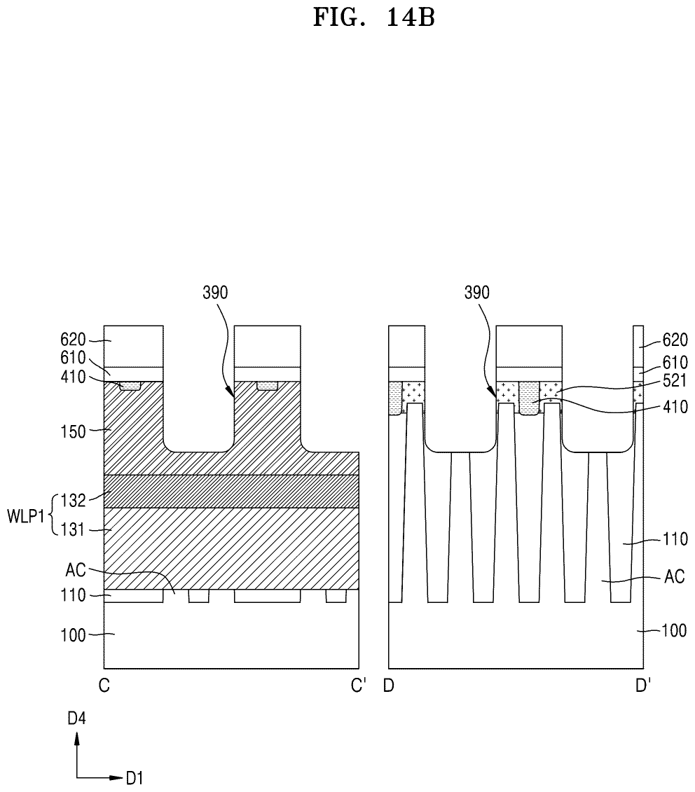

Referring to FIGS. 14A and 14B, an etching process may be performed on the upper insulation layer 620 to form contact trenches 390. The etching process may be performed by using a fourth mask pattern (not shown). The contact trenches 390 may extend in the first direction D1 in a plan view. The contact trenches 390 may be formed in the first capping patterns 150. The contact trenches 390 may extend (e.g., penetrate) through the upper insulation layer 620, the lower insulation layer 610, and the lower contact patterns 521. In the process of forming the contact trenches 390, upper portions of the active patterns AC may be further recessed. The bottom surfaces of the contact trenches 390 may expose the active patterns AC, the device isolation layer 110, and the first capping patterns 150.

Afterwards, a fourth mask pattern removal process and an etching residue removal

process may be further performed. The fourth mask pattern may be removed through a stripping process. Etching residues may be removed through an ashing process.

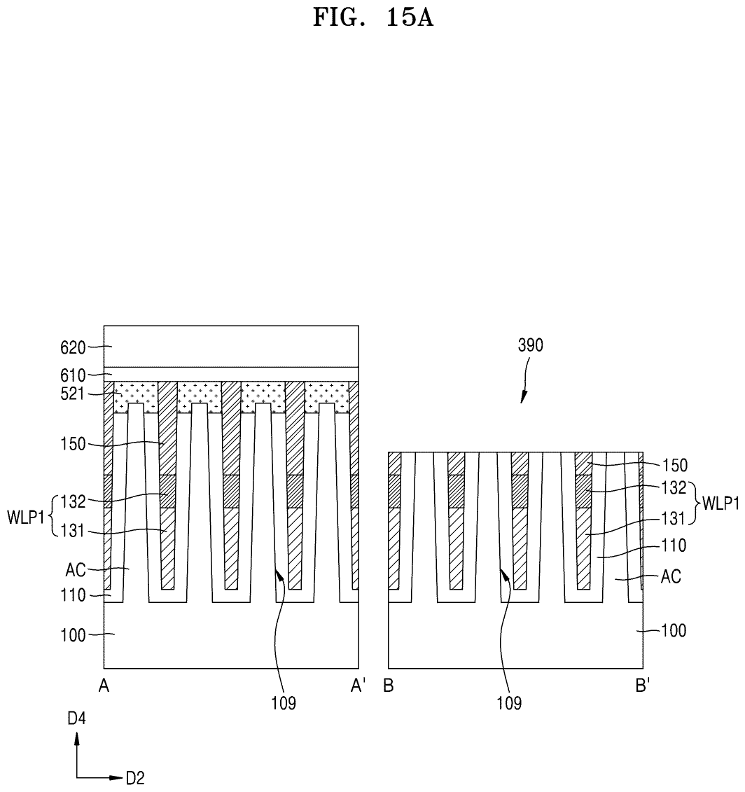

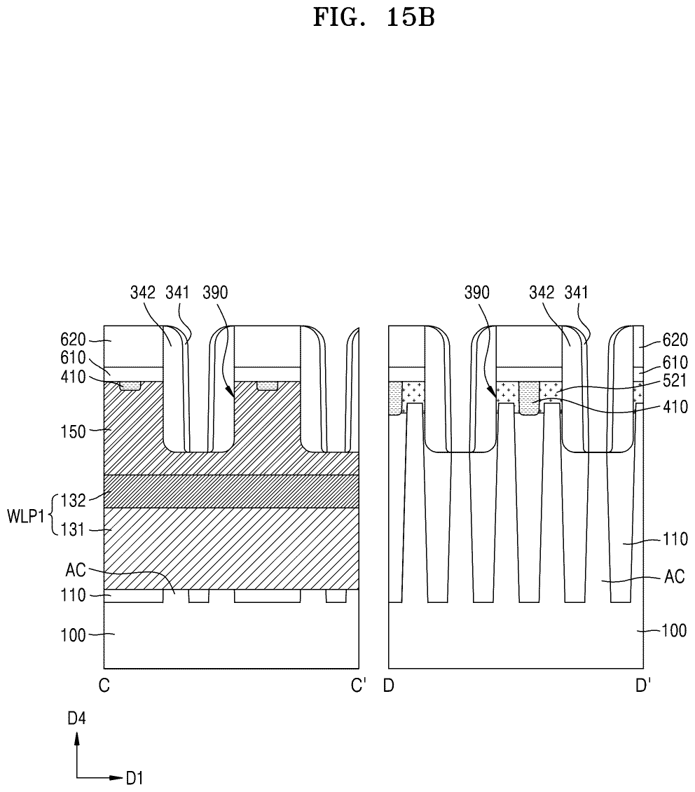

Referring to FIGS. 15A and 15B, the second spacers 342 may be formed on the sidewalls of the contact trenches 390 and may be on (e.g., may cover) the sidewalls of the lower contact patterns 521 and the sidewalls of the first capping patterns 150. The second spacers 342 may extend in the second direction D2 and may be spaced apart from each other. Formation of the second spacers 342 may include forming a second spacer film that conformally covers the upper insulation layer 620 and the contact trenches 390 and removing a portion of the second spacer film through an etching process.

The first spacers 341 may be formed in the contact trenches 390 and may be on (e.g., may cover) the sidewalls of the second spacers 342. The first spacers 341 may be horizontally spaced apart from the first capping patterns 150 and the lower contact patterns 521 by the second spacers 342. The first spacers 341 may extend in the second direction D2 and may be spaced apart from each other, in a plan view.

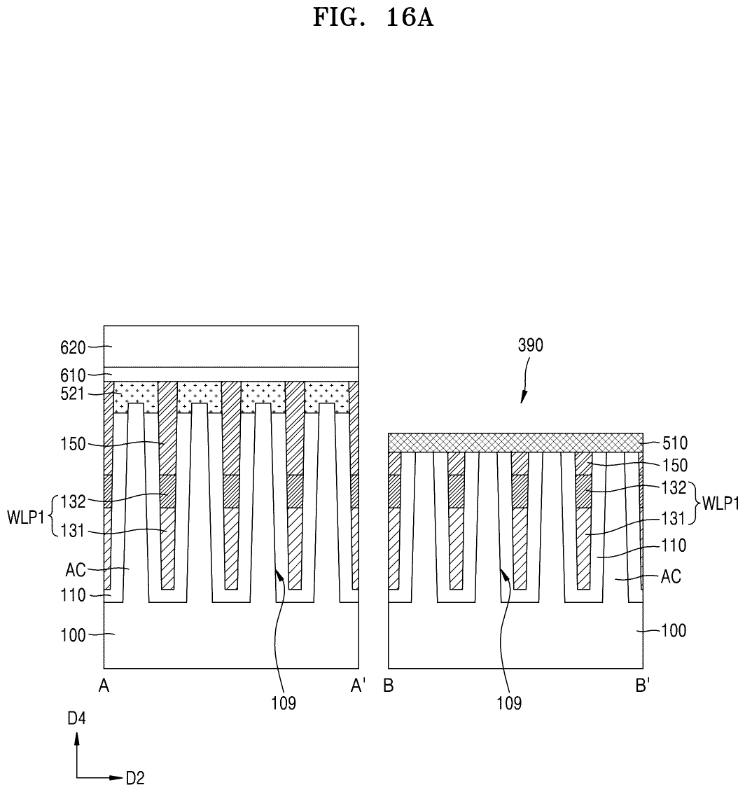

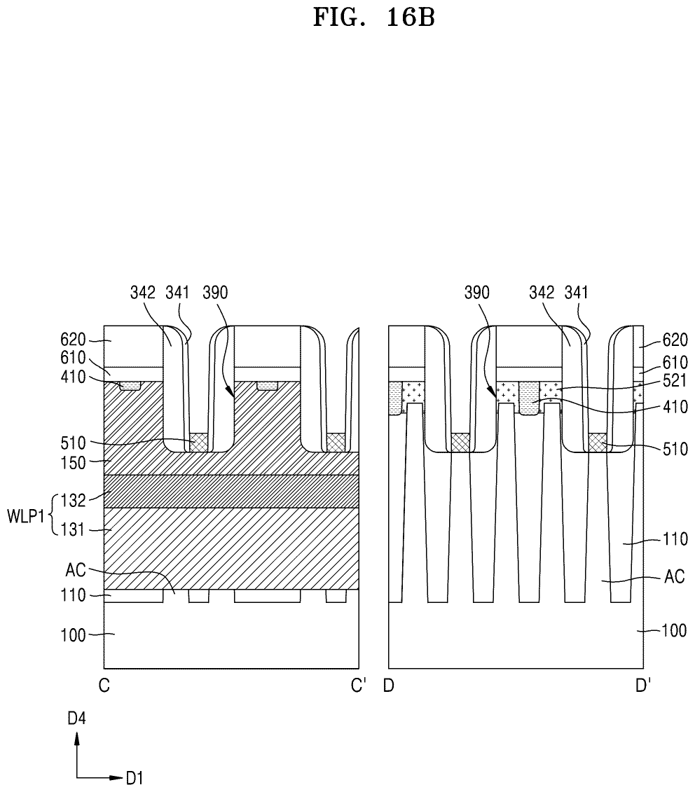

Referring to FIGS. 16A and 16B, the first contact patterns 510 may be formed in the contact trenches 390 and on the top surfaces of the active patterns AC. The first contact patterns 510 may contact the recessed top surfaces of the plurality of active patterns AC, respectively. The first contact patterns 510 may be on (e.g., may cover) the sidewalls of the first spacers 341. The first contact patterns 510 may each be localized below a corresponding contact trench 390. For example, the top surfaces of the first contact patterns 510 may be provided at a lower level than the top surface of the upper insulation layer 620 in the fourth direction D4. The first contact patterns 510 may each extend in the second direction D2 in a plan view. The first contact patterns 510 may be spaced apart from each other. The first contact patterns 510 may include polysilicon, and the polysilicon may be doped with a Group III element or a Group V element.

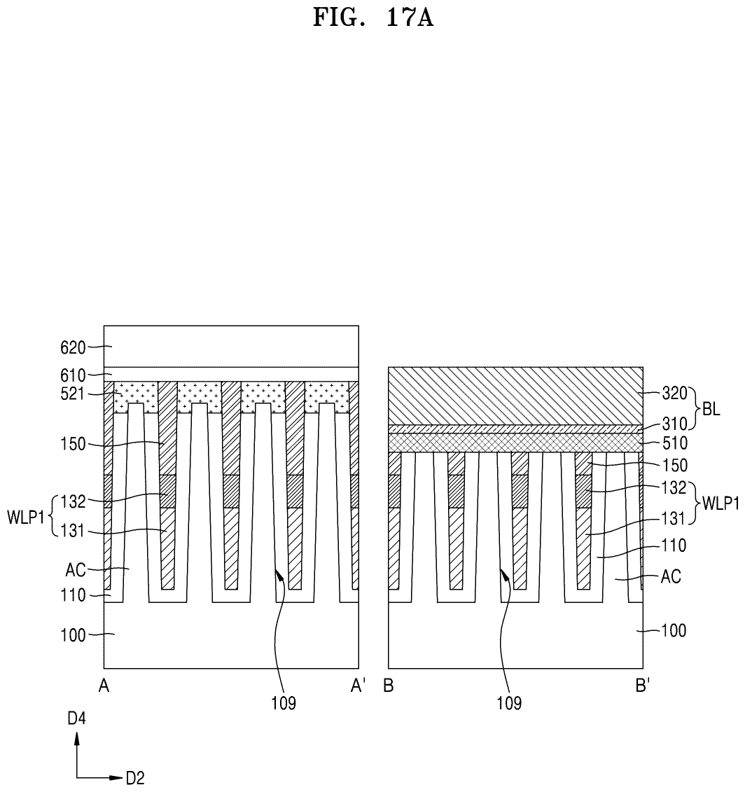

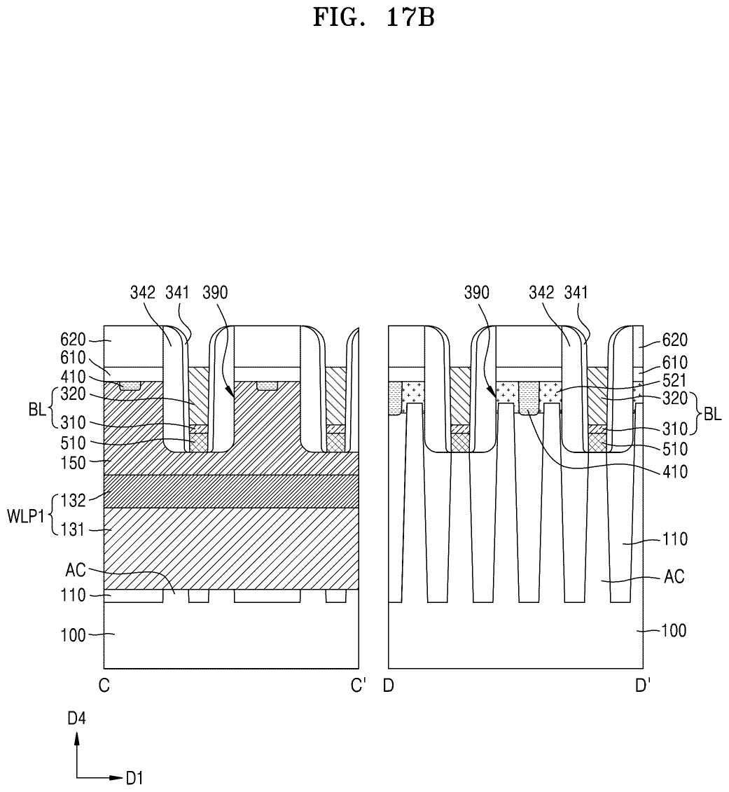

Referring to FIGS. 17A and 17B, the bit lines BL may be formed in the contact trenches 390 and on the first contact patterns 510 and may contact the first contact patterns 510. The bit lines BL may be connected to the active patterns AC through the first contact patterns 510. The bit lines BL may be localized in the contact trenches 390, respectively. The bit lines BL may extend in the second direction D2 in a plan view and may be spaced apart from each other. The bit lines BL may be on (e.g., may cover) outer sidewalls of the second spacers 342. The bit lines BL may each include the lower conductive pattern 310 and the upper conductive pattern 320. The lower conductive pattern 310 and the upper conductive pattern 320 may each extend in the second direction D2.

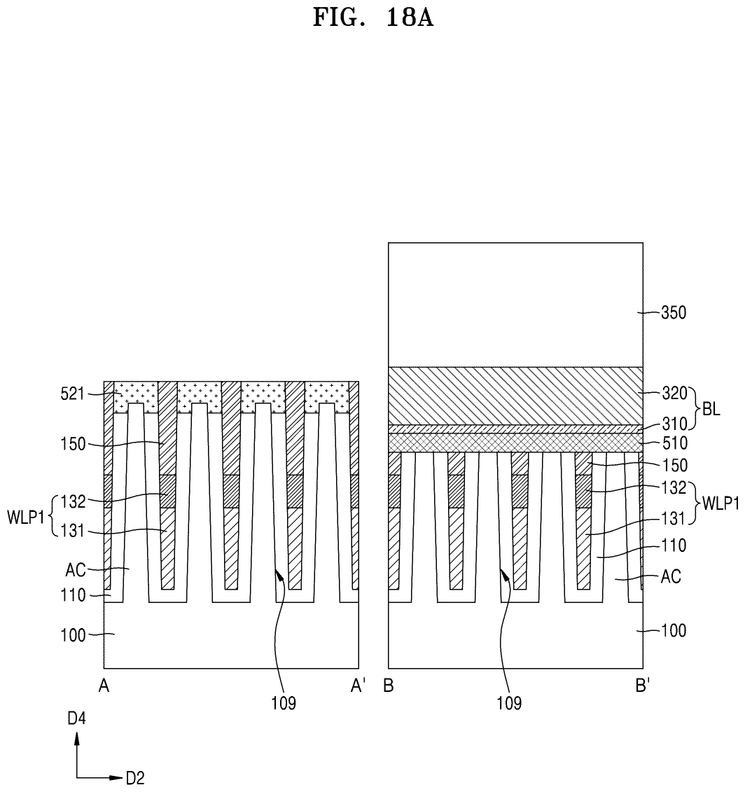

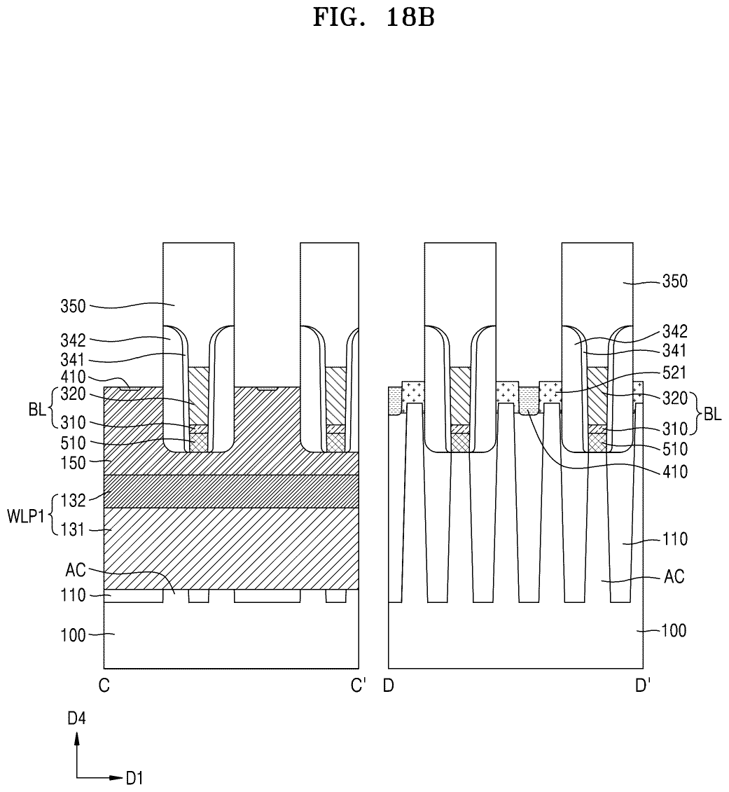

Referring to FIGS. 18A and 18B, the insulation capping patterns 350 may be formed on the bit lines BL to cover the bit lines BL. Formation of the insulation capping patterns 350 may include forming an insulation capping layer on the bit lines BL, the first spacers 341, the second spacers 342, the first capping patterns 150, the lower contact patterns 521, and the first insulation patterns 410 and etching the insulation capping layer. The insulation capping layer may be formed through a deposition process and a polishing process. A portion of the insulation capping layer may be removed through the etching process, thereby forming the insulation capping patterns 350. The insulation capping patterns 350 may expose the top surfaces of the lower contact patterns 521, the top surfaces of the first capping patterns 150, and the top surfaces of the first insulation patterns 410. The insulation capping patterns 350 may be further provided on the top surfaces of the first spacers 341 and the top surfaces of the second spacers 342.

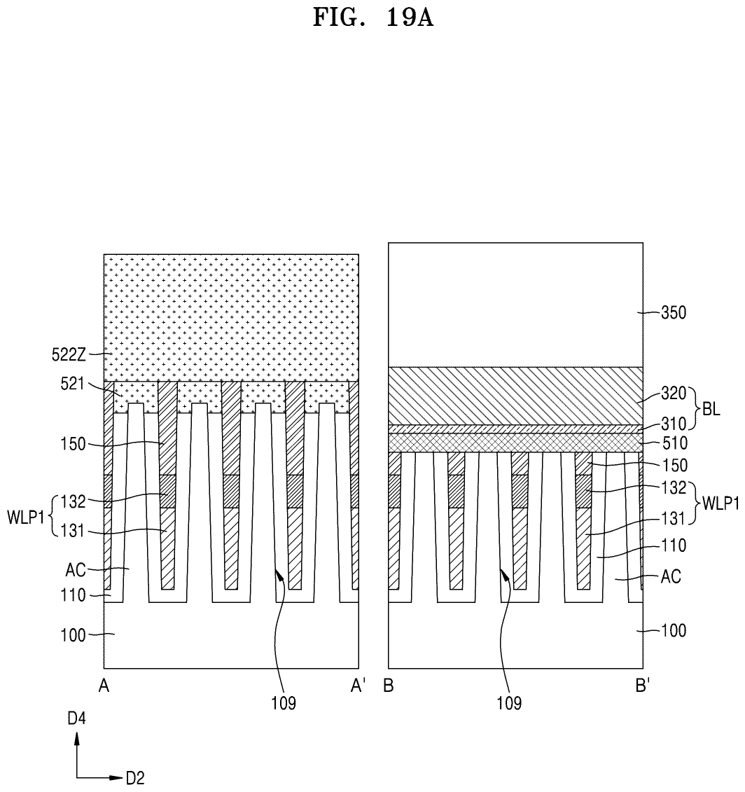

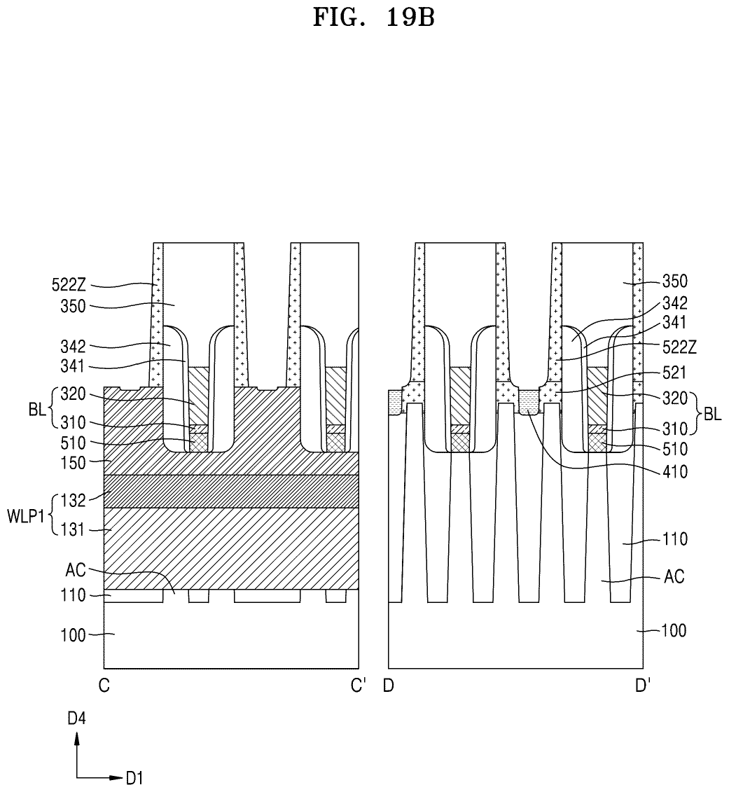

Referring to FIGS. 19A and 19B, an upper contact layer 522Z may be formed on the lower contact patterns 521 and the first capping patterns 150. The upper contact layer 522Z may be on (e.g., may cover) the sidewalls of the insulation capping patterns 350 and the sidewalls of the first spacers 341. The upper contact layer 522Z may not extend onto top surfaces of the insulation capping patterns 350.

Formation of the upper contact layer 522Z may include forming the upper contact layer 522Z through a deposition process and removing a portion of the upper contact layer 522Z through an etching process. In the etching process, portions of the first insulation patterns 410 on the first capping patterns 150 may be removed together with a portion of the upper contact layer 522Z.

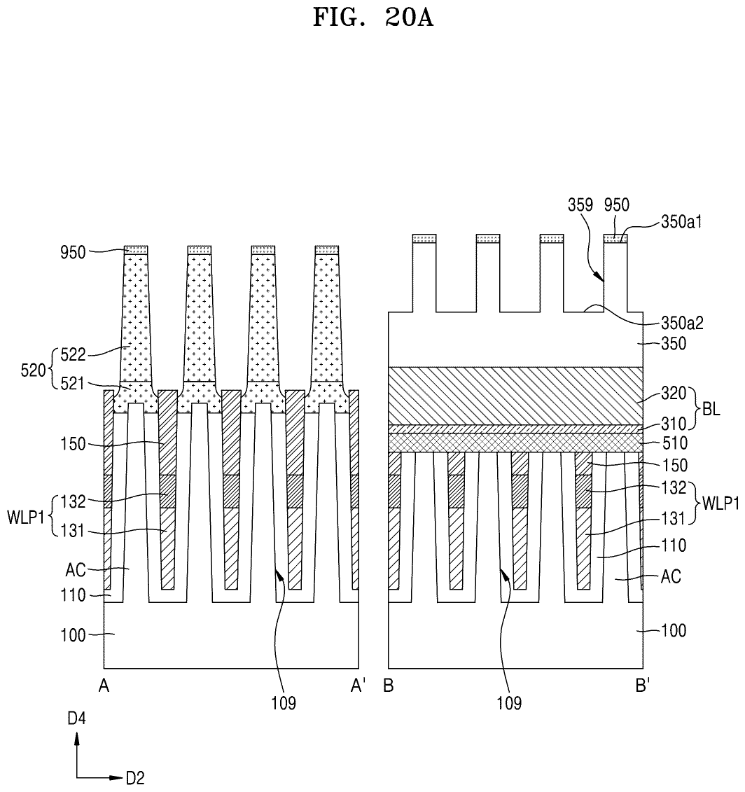

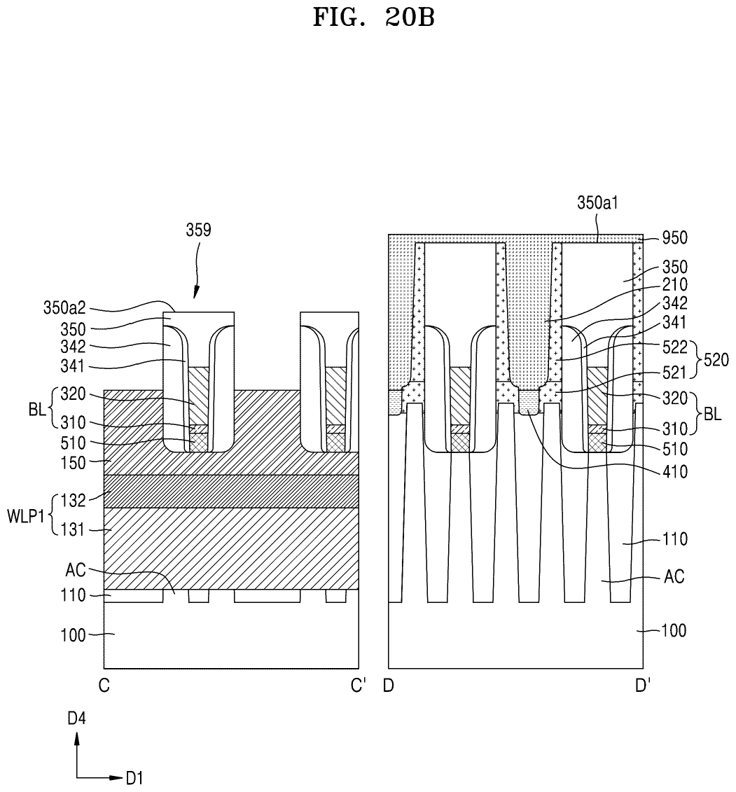

Referring to FIGS. 20A and 20B together with FIGS. 19A and 19B, a fifth mask pattern 950 may be formed on the upper contact layer 522Z and the insulation capping patterns 350. The fifth mask pattern 950 may further be on (e.g., may cover) the top surfaces of the first insulation patterns 410. Openings of the fifth mask pattern 950 may expose the insulation capping patterns 350 and the upper contact layer 522Z. For example, the fifth mask pattern 950 may include an organic layer such as a spin-on-hard mask (SOH) or an amorphous carbonization layer.

An etching process using the fifth mask pattern 950 may be performed on the upper contact layer 522Z to form a plurality of upper contact patterns 522 separated from each other. The upper contact patterns 522 may be spaced apart from each other in the second direction D2. The etching process may be performed until the first capping patterns 150 between the upper contact patterns 522 are exposed. As a result of the etching process, the second contact patterns 520 may be formed. The second contact patterns 520 may each include at least one of the lower contact patterns 521 and at least one of the upper contact patterns 522.

During the etching process, the upper portions of the insulation capping patterns 350 may be etched together. Therefore, the upper trenches 359 may be formed in the upper portions of the insulation capping patterns 350. The upper trenches 359 extend (e.g., penetrate) through first top surfaces 350a1 of the insulation capping patterns 350, and the bottom surfaces of the upper trenches 359 may be provided in the insulation capping patterns 350. Therefore, the insulation capping patterns 350 may have the first top surfaces 350a1 and second top surfaces 350a2. The second top surfaces 350a2 of the insulation capping patterns 350 may correspond to the bottom surfaces of the upper trenches 359. The second top surfaces 350a2 of the insulation capping patterns 350 may be provided at a lower level than the first top surfaces 350a1 in the fourth direction D4. The upper trenches 359 may be spaced apart from each other in the second direction D2.

The fifth mask pattern 950 may be removed through a stripping process to expose the top surfaces of the insulation capping patterns 350 and second contact patterns 520. Afterwards, an ashing process may be performed to remove etching residues.

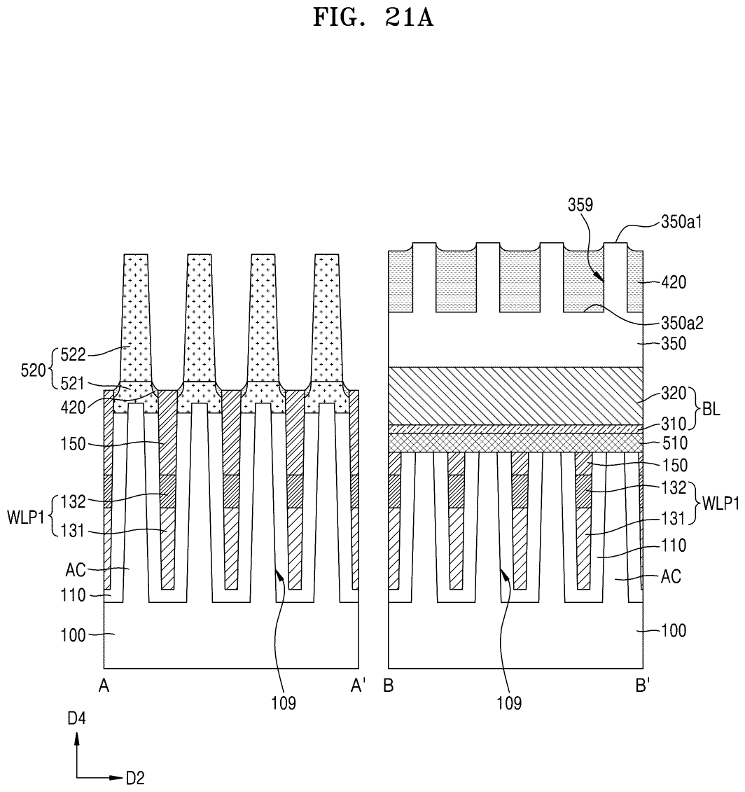

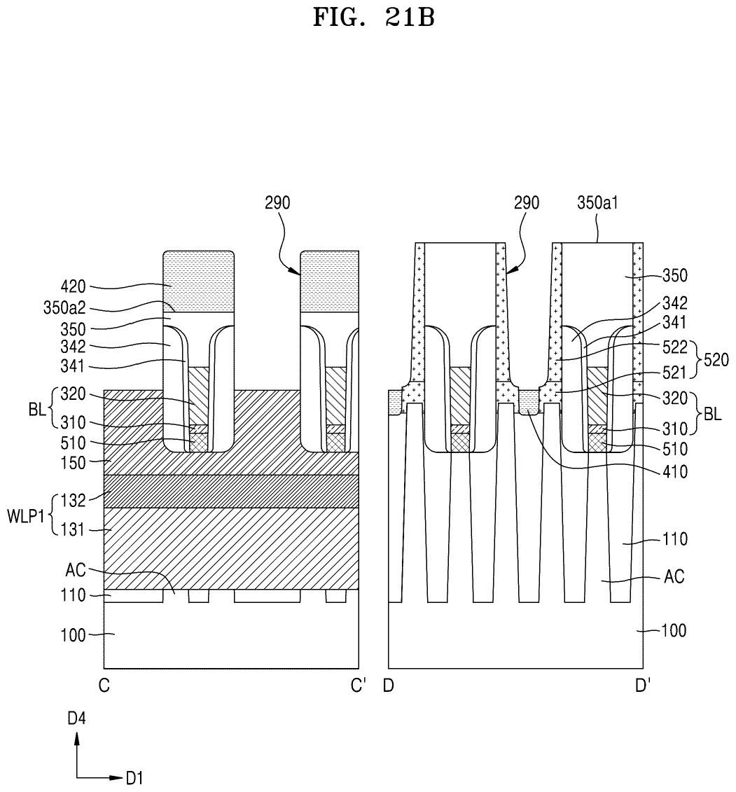

Referring to FIGS. 21A and 21B, the second insulation patterns 420 may be formed in the upper trenches 359 to be on (e.g., to cover) the second top surfaces 350a2 of the insulation capping patterns 350. The top surfaces of the second insulation patterns 420 may be provided at a lower level than the first top surfaces 350a1 of the insulation capping patterns 350 in the fourth direction D4. Formation of the second insulation patterns 420 may include forming a third insulation layer covering the top surfaces of the second contact patterns 520 and the first top surfaces 350a1 of the insulation capping patterns 350 and performing an etchback process on the third insulation layer. The etchback process may include a wet etchback process or an isotropic etchback process. The second insulation patterns 420 may expose the top surfaces of the second contact patterns 520 and the first top surfaces 350a1 of the insulation capping patterns 350. The second insulation patterns 420 may further be on (e.g., may cover) the sidewalls of the lower contact pattern 521.

Second word line trenches 290 may be provided. The second word line trenches 290 may extend in the second direction D2 in a plan view. The second word line trenches 290 may expose the sidewalls of the second insulation patterns 420, the sidewalls of the insulation capping patterns 350, the sidewalls of the upper portions of the second spacers 342, the top surfaces of the first capping patterns 150, the sidewalls of the second contact patterns 520, and the top surfaces of the first insulation patterns 410.

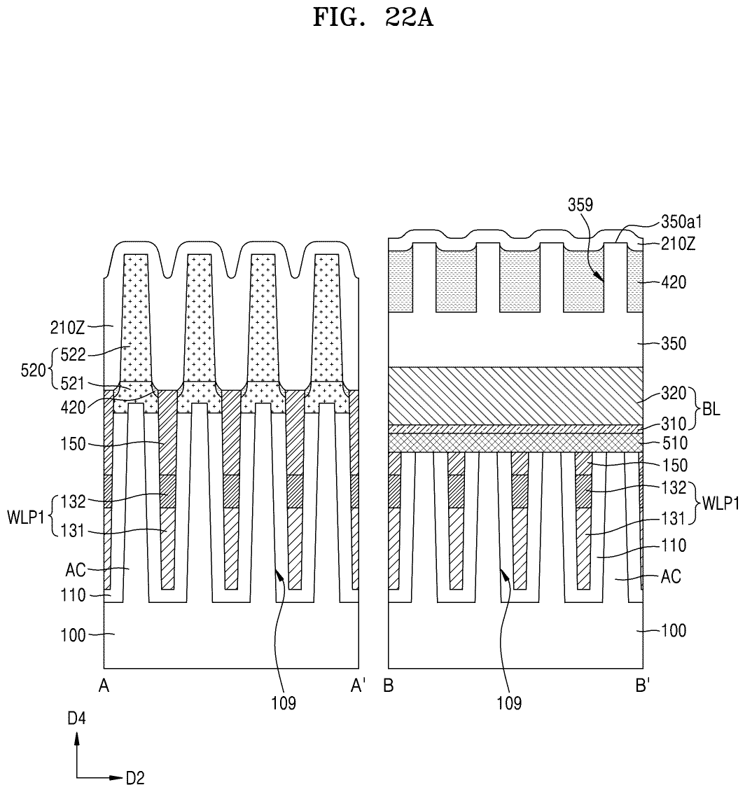

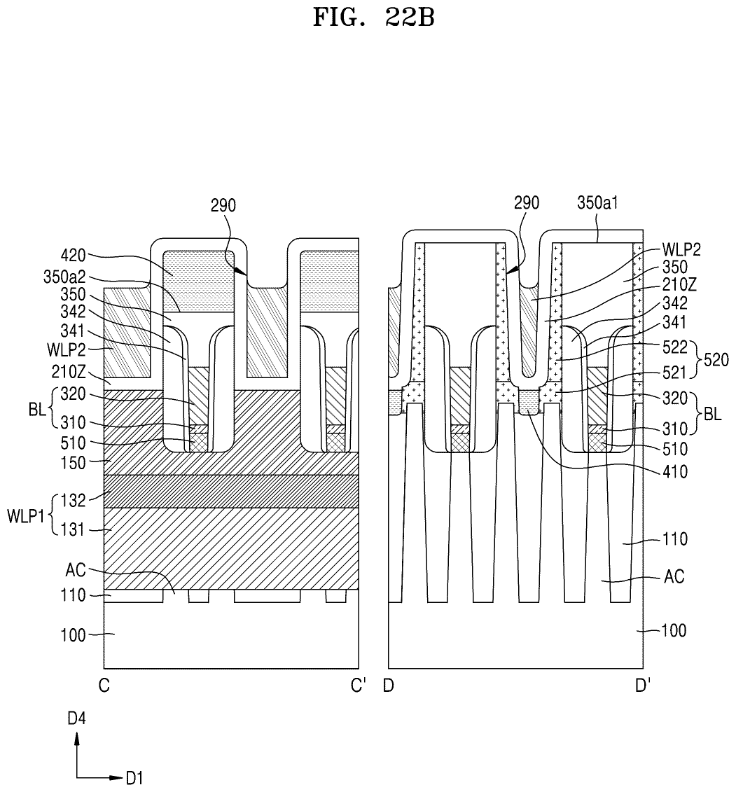

Referring to FIGS. 22A and 22B, a gate insulation layer 210Z may be formed on the second contact patterns 520 and the first top surfaces 350a1 of the insulation capping patterns 350 and may be on (e.g., may cover) the bottom surfaces and the sidewalls of the second word line trenches 290. The gate insulation layer 210Z may fill gap regions between the second contact patterns 520 in the second direction D2. The gate insulation layer 210Z may be on (e.g., may cover) the top surface of the lower contact pattern 521 and the sidewall of the upper contact pattern 522. The gate insulation layer 210Z may be formed through a deposition process.

The second word line patterns WLP2 may be formed in the second word line trenches 290 and may be on (e.g., may cover) the gate insulation layer 210Z. The top surfaces of the second word line patterns WLP2 may be provided at a lower level than the top surfaces of the gate insulation layer 210Z in the fourth direction D4. Formation of the second word line patterns WLP2 may include forming a conductive film through a deposition process and performing an etchback process on the conductive film. The second word line patterns WLP2 may be localized in the second word line trenches 290 through the etch-back process. The second word line patterns WLP2 may extend in the second direction D2 in a plan view. The second word line patterns WLP2 may be spaced apart from each other.

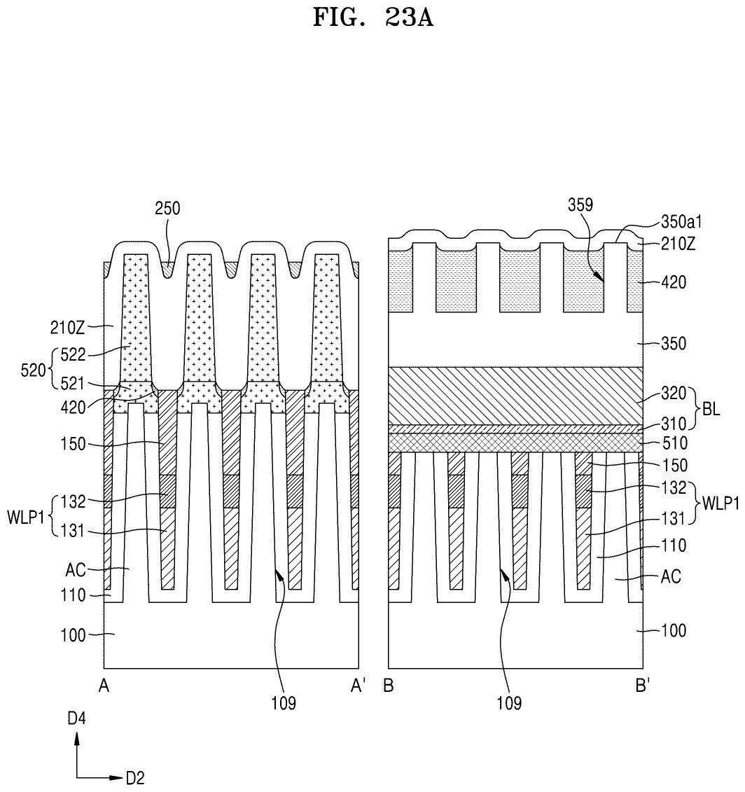

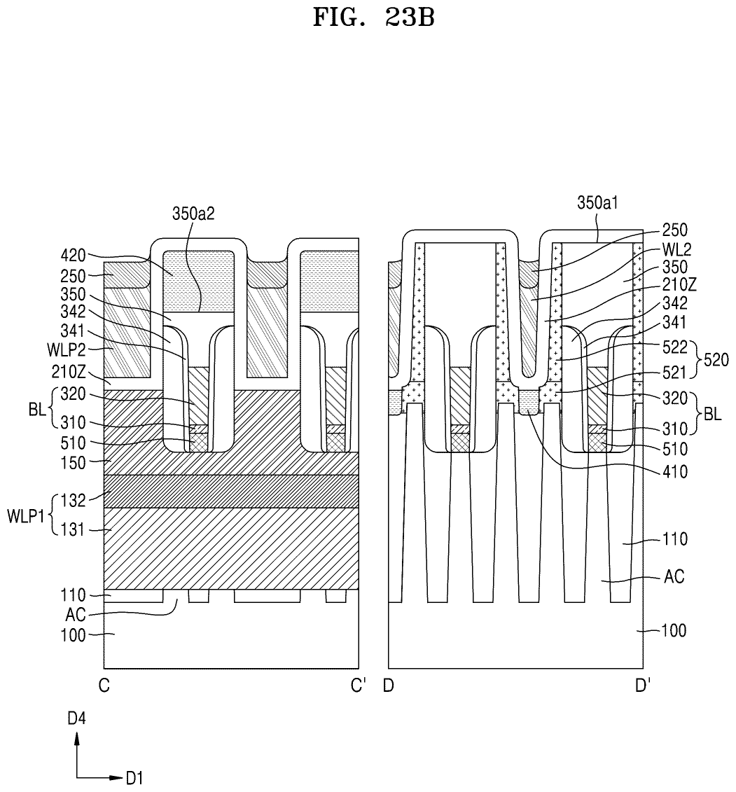

Referring to FIGS. 23A and 23B, the second capping patterns 250 may be formed in the second word line trenches 290 and may be on (e.g., may cover) the top surfaces of the second word line patterns WLP2. The second capping patterns 250 may further be on (e.g., may cover) the sidewalls of the gate insulation layer 210Z. The planar shape of the second capping patterns 250 may be identical or similar to the planar shape of the second word line trenches 290. The second capping patterns 250 may extend in the second direction D2 in a plan view. Formation of the second capping patterns 250 may include forming a second capping layer through a deposition process and removing a portion of the second capping layer through an etchback process.

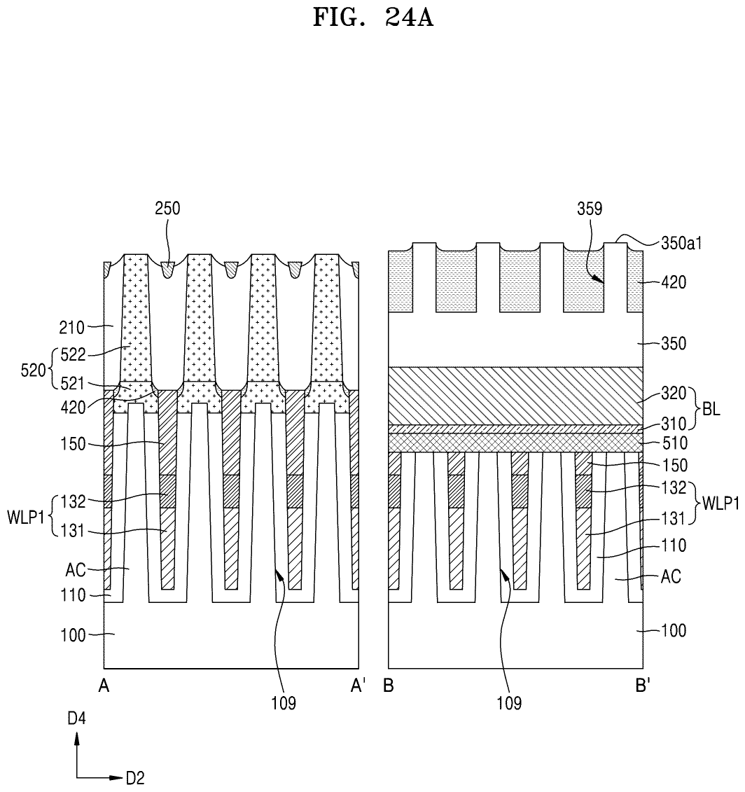

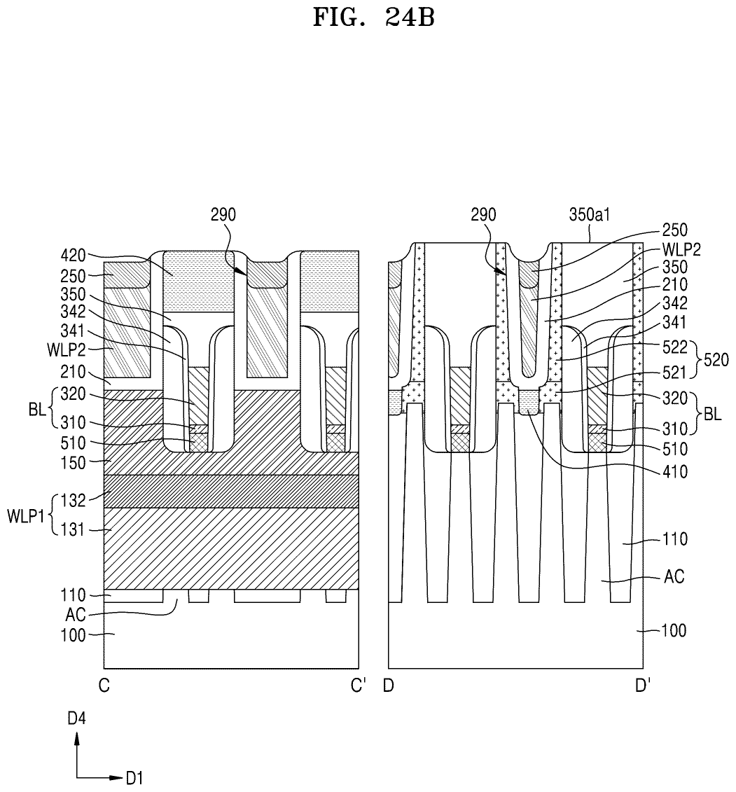

Referring to FIGS. 24A and 24B, a portion of the gate insulation layer 210Z may be removed to form the gate insulation patterns 210. A portion of the gate insulation layer 210Z may be removed through an etching process. The gate insulation patterns 210 may be arranged between the second word line patterns WLP2 and the second contact patterns 520. The gate insulation patterns 210 may be in (e.g., may fill) gap regions between the second contact patterns 520 in the first direction D1. The arrangement of the gate insulation patterns 210 may be identical to that described in the examples of FIGS. 4B, 4C, and 4D. The gate insulation patterns 210 may expose the top surfaces of the second contact patterns 520, the top surfaces of the second insulation patterns 420, and the first top surfaces 350a1 of the insulation capping patterns 350.

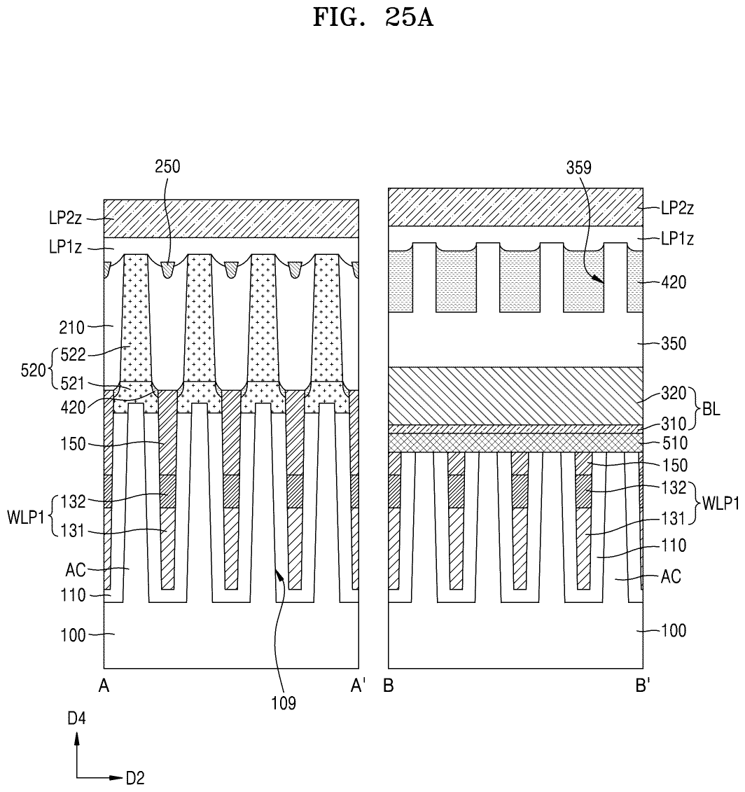

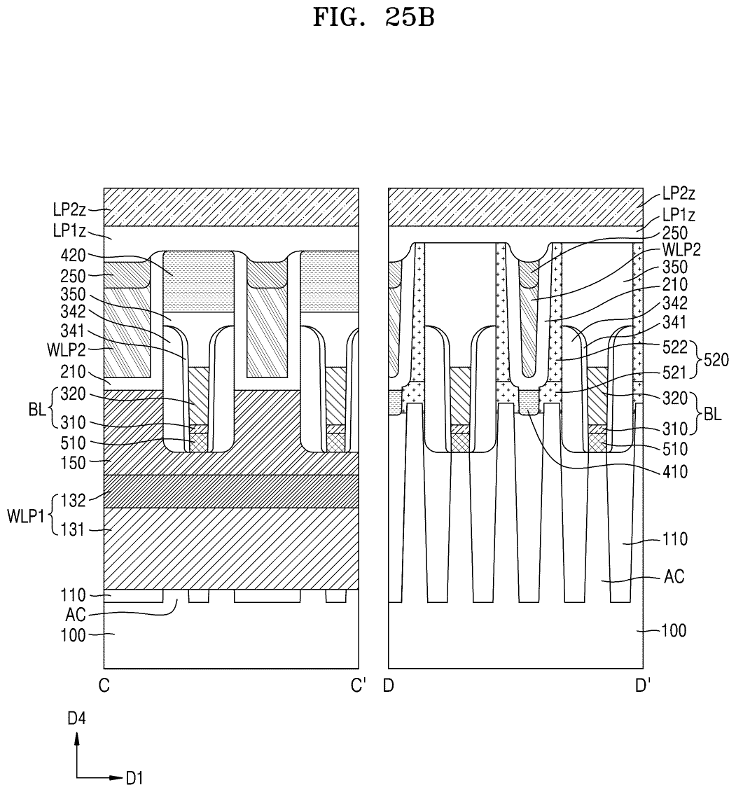

Referring to FIGS. 25A and 25B, a first landing layer LP1z may be formed on the top surface of the upper contact pattern 522, the top surfaces of the second insulation patterns 420, the first top surfaces 350a1 of the insulation capping patterns 350, the top surfaces of the second capping patterns 250, and the top surfaces of the gate insulation patterns 210. The first landing layer LP1z may be formed by depositing a metal material. A second landing layer LP2z may be formed on the first landing layer LP1z. The second landing layer LP2z may be formed through a deposition process using a metal material different from that of the first landing layer LP1z.

Referring back to FIGS. 4B and 4C, a portion of the second landing layer LP2z may be removed to form the second landing pad LP2, and a portion of the first landing layer LP1z may be removed to form the first landing pad LP1. A portion of the first landing layer LP1z and a portion of the second landing layer LP2z may be removed through an etching process using a mask pattern. Therefore, the landing pads LP may be formed, and the landing pads LP may each include the first landing pad LP1 and the second landing pad LP2. The landing pads LP are formed on the second contact patterns 520 and may be connected to the active patterns AC through the second contact patterns 520. The semiconductor device 1 may be manufactured according to the examples described above.

According to the inventive concepts, a semiconductor device may include bit lines, a first word line, and a second word line. The second word line may be placed between the bit lines. Therefore, the spacing between bit lines may increase, and thus the difficulty of the process of manufacturing a semiconductor device may be reduced. As the number of bit lines decreases, the area of sense amplifiers increases, and the number of pad terminals connected to the sense amplifiers may decrease. The pad terminals may be electrically connected to an external device through connection wires. The difficulty of the process of manufacturing connection wires may be reduced. Therefore, the difficulty of the process of manufacturing a semiconductor device may be further reduced. Semiconductor devices may be miniaturized.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof. In addition, it will be understood that, although the terms “first”, “second”, etc. may be used herein to describe various elements, these elements should not be limited by these terms. Rather, these terms are only used to distinguish one element from another. For example, a first element could be termed a second element, and, similarly, a second element could be termed a first element, without departing from the scope of the present disclosure.

While the inventive concepts have been particularly shown and described with reference to example embodiments thereof, it will be understood that various changes in form and details may be made therein without departing from the scope of the following claims.

What is claimed is:

1. A semiconductor device comprising:
a first word line extending in a first direction;
bit lines extending in a second direction different from the first direction in a plan view;
a second word line between ones of the bit lines and extending in the second direction; and
a first memory cell,
wherein the first memory cell comprises:
a first transistor electrically connected to a first one of the bit lines and the first word line;
a second transistor electrically connected to the second word line and including source/drain electrodes; and
a capacitor electrically connected to the second transistor, and
wherein one of the source/drain electrodes of the second transistor is electrically connected to the first transistor.

2. The semiconductor device of claim 1, wherein another one of the source/drain electrodes of the second transistor is electrically connected to the capacitor.

3. The semiconductor device of claim 1, further comprising a second memory cell,
wherein the first memory cell and the second memory cell are between the first one of the bit lines and a second one of the bit lines adjacent to the first one of the bit lines, and
wherein the second memory cell is electrically connected to the second one of the bit lines, the first word line, and the second word line.

4. The semiconductor device of claim 3, wherein the second memory cell comprises:
a third transistor electrically connected to the second one of the bit lines and the first word line;
a fourth transistor electrically connected to the second word line and including source/drain electrodes; and
a capacitor electrically connected to the fourth transistor.

5. The semiconductor device of claim 4, wherein one of the source/drain electrodes of the fourth transistor is electrically connected to the third transistor.

6. The semiconductor device of claim 1, further comprising a second memory cell comprising a third transistor, a fourth transistor, and a capacitor,
wherein the second word line is a first sub-word line,
wherein the semiconductor device further comprises a second sub-word line extending in the second direction,
wherein the first sub-word line is electrically connected to the second transistor of the first memory cell, and
wherein the second sub-word line is electrically connected to the fourth transistor of the second memory cell.

7. The semiconductor device of claim 6, further comprising:
a first voltage supply line electrically connected to the first sub-word line and electrically separated from the second sub-word line; and
a second voltage supply line electrically connected to the second sub-word line and electrically separated from the first sub-word line.

8. A semiconductor device comprising:
a first memory cell and a second memory cell adjacent to each other, wherein each of the first memory cell and the second memory cell comprises a first transistor, a second transistor, and a capacitor;
a first word line electrically connected to the first transistor of each of the first memory cell and the second memory cell;
a bit line electrically connected to the first transistor of each of the first memory cell and the second memory cell; and
second word lines electrically connected to the second transistor of the first memory cell and the second transistor of the second memory cell, respectively.

9. The semiconductor device of claim 8, wherein the bit line is between the second word lines in a plan view,
wherein the second transistor of the first memory cell is electrically connected to the first transistor of the first memory cell and the capacitor of the first memory cell, and
wherein the second transistor of the second memory cell is electrically connected to the first transistor of the second memory cell and the capacitor of the second memory cell.

10. The semiconductor device of claim 8, wherein the first word line extends in a first direction in a plan view,
wherein the bit line extends in a second direction different from the first direction in the plan view, and
wherein the second word lines extend in the second direction in the plan view.

11. The semiconductor device of claim 8, wherein the second word lines comprise:
a first sub-word line electrically connected to the second transistor of the first memory cell; and
a second sub-word line electrically connected to the second transistor of the second memory cell, and
wherein the bit line is between the first sub-word line and the second sub-word line.

12. The semiconductor device of claim 11, further comprising:
a first word line driver electrically connected to the first word line;
a second word line driver electrically connected to the first sub-word line; and
a third word line driver electrically connected to the second sub-word line.

13. The semiconductor device of claim 12, further comprising:
a sense amplifier electrically connected to the bit line;
a row decoder electrically connected to the first word line driver; and
a column decoder electrically connected to the sense amplifier, the second word line driver, and the third word line driver.

14. A semiconductor device comprising:
active patterns protruding from a substrate;
first word line patterns between the active patterns and extending in a first direction in a plan view;
a device isolation layer on the substrate and between the active patterns and the first word line patterns;
bit lines on the active patterns and the first word line patterns, crossing the active patterns and the first word line patterns in the plan view, and extending in a second direction in the plan view;
first contact patterns between the active patterns and the bit lines and contacting the active patterns and the bit lines;
second word line patterns on the device isolation layer and between the bit lines in the plan view;
second contact patterns between the bit lines and the second word line patterns and contacting the active patterns; and
landing pads on the second contact patterns and electrically connected to the second contact patterns,
wherein the second word line patterns extend in the second direction, and
wherein the second direction is different from the first direction.

15. The semiconductor device of claim 14, wherein bottom surfaces of the second word line patterns are at a higher level than bottom surfaces of the bit lines in a third direction substantially perpendicular to a bottom surface of the substrate, with the bottom surface of the substrate providing a base reference plane.

16. The semiconductor device of claim 14, wherein the first contact patterns extend between the first word line patterns and the bit lines and between the device isolation layer and the bit lines.

17. The semiconductor device of claim 16, wherein the first contact patterns extend in the second direction in the plan view.

18. The semiconductor device of claim 14, further comprising gate insulation patterns on sidewalls and bottom surfaces of the second word line patterns, wherein the gate insulation patterns are between sidewalls of the second contact patterns and the sidewalls of the second word line patterns.

19. The semiconductor device of claim 14, wherein bottom surfaces of the second contact patterns are at a lower level than bottom surfaces of the second word line patterns in a third direction substantially perpendicular to a bottom surface of the substrate, with the bottom surface of the substrate providing a base reference plane, and
wherein top surfaces of the second contact patterns are at a higher level than top surfaces of the second word line patterns in the third direction, with the bottom surface of the substrate providing the base reference plane.

20. The semiconductor device of claim 14, wherein each of the second contact patterns comprises:
a lower contact pattern contacting at least one of the active patterns; and
an upper contact pattern on the lower contact pattern,
wherein a thickness of the upper contact pattern is greater than a thickness of the lower contact pattern in a third direction substantially perpendicular to a bottom surface of the substrate, and
wherein an impurity concentration of the lower contact pattern is greater than that of the upper contact pattern.
